(19) United States
(12) Patent Application Publication
(10) Pub. No.: US 2025/0240974 A1
(43) Pub. Date: Jul. 24, 2025

(54) VARIABLE RESISTANCE MEMORY DEVICE

(71) Applicant: Samsung Electronics Co., Ltd., Suwon-si (KR)

(72) Inventors: Hasung SIM, Suwon-si (KR); Byungkweon JANG, Suwon-si (KR); Giwoong KWON, Suwon-si (KR); Taeyoung LEE, Suwon-si (KR); Shinhee HAN, Suwon-si (KR)

(73) Assignee: Samsung Electronics Co., Ltd., Suwon-si (KR)

(21) Appl. No.: 18/952,179

(22) Filed: Nov. 19, 2024

(30) Foreign Application Priority Data
Jan. 18, 2024 (KR) 10-2024-0008285

(51) Int. Cl. H10B 61/00

(52) U.S. Cl. CPC H10B 61/10

(57) ABSTRACT

A variable resistance memory device includes a cell array region in which memory cells are arranged apart from each other in a row direction and a column direction, the cell array region including a main cell region in which active cells from among the memory cells are arranged apart from each other and a dummy cell region which is outside the main cell region and in which dummy cells are located in N (N is a natural number greater than or equal to 2) columns from among the memory cells, and a peripheral circuit region surrounding the cell array region. First dummy cells located in at least one column adjacent to the main cell region are connected to a first cell wiring line, and second dummy cells located in at least one column adjacent to the peripheral circuit region are not connected to the first cell wiring line.

### CROSS-REFERENCE TO RELATED APPLICATION

This application is based on and claims priority under 35 U.S.C. § 119 to Korean Patent Application No. 10-2024-0008285, filed on Jan. 18, 2024, in the Korean Intellectual Property Office, the disclosure of which is incorporated by reference herein in its entirety.

### BACKGROUND

The inventive concepts relate to a variable resistance memory device, and more particularly, to a variable resistance memory device for improving process reliability and suppressing occurrence of defects.

The operating speed and integration of memory devices used in semiconductor products need to be increased. To satisfy this need, variable resistance memory devices have been proposed. The variable resistance memory device may utilize the current transfer characteristics of a variable resistance layer depending on an applied voltage. A representative example of the variable resistance memory device is magnetoresistive random access memory (MRAM).

### SUMMARY

The inventive concepts provide a variable resistance memory device for improving process reliability and suppressing occurrence of defects.

According to an aspect of the inventive concepts, there is provided a variable resistance memory device including a cell array region in which a plurality of memory cells are arranged apart from each other in a row direction and a column direction perpendicular to the row direction, the cell array region including a main cell region in which a plurality of active cells from among the memory cells are arranged apart from each other and a dummy cell region which is outside the main cell region and in which dummy cells are located in N (N is a natural number greater than or equal to 2) columns from among the memory cells, and a peripheral circuit region surrounding the cell array region. First dummy cells located in at least one column adjacent to the main cell region from among the dummy cells are connected to a first cell wiring line, and second dummy cells located in at least one column adjacent to the peripheral circuit region from among the dummy cells are not connected to the first cell wiring line.

According to another aspect of the inventive concepts, there is provided a variable resistance memory device including a cell array region in which E (E is a natural number greater than or equal to 1) memory cells are apart from each other in a row direction and F (F is a natural number greater than or equal to 1) memory cells are arranged apart from each other in a column direction perpendicular to the row direction, the cell array region including a main cell region in which a plurality of active cells from among the memory cells are apart from each other and a cell peripheral region which is outside the main cell region and in which dummy cells are arranged in N (N is a natural number greater than or equal to 2) columns from among the memory cells, and a peripheral circuit region surrounding the cell peripheral region.

First dummy cells located in at least one column adjacent to the main cell region from among the dummy cells are connected to a first cell wiring line, and second dummy cells located in one outermost column of the main cell region or located in outer N−1 (N is a natural number greater than or equal to 2) columns of the main cell region from among the dummy cells are not connected to the first cell wiring line.

According to another aspect of the inventive concepts, there is provided a variable resistance memory device including a substrate including a main cell region, a cell array region including a dummy cell region located at one side of the main cell region, and a peripheral circuit region located at one side of the cell array region, a cell transistor formed in the cell array region of the substrate, a plurality of cell contact plugs located in the main cell region above the substrate and connected to the cell transistor, and a plurality of dummy cell contact plugs located in the dummy cell region above the substrate and not connected to the cell transistor while being apart from the cell contact plugs.

The variable resistance memory device includes a plurality of active cells located on the cell contact plugs and connected to the cell contact plugs, and a plurality of dummy cells located on the dummy cell contact plugs and connected to the dummy cell contact plugs, the dummy cells including at least one first dummy cell located adjacent to the main cell region and at least one second dummy cell located adjacent to the peripheral circuit region.

The variable resistance memory device includes a first cell wiring line located on the active cells and the at least one first dummy cell and not connected to the at least one second dummy cell while being connected to the active cells and the at least one first dummy cell, and a bit line located on the first cell wiring line and connected to the first cell wiring line.

### BRIEF DESCRIPTION OF THE DRAWINGS

Embodiments will be more clearly understood from the following detailed description taken in conjunction with the accompanying drawings in which:

FIG. 1 is a circuit diagram showing a cell array of a variable resistance memory device according to at least one embodiment;

FIG. 2 is a circuit diagram showing a magnetoresistive memory cell of FIG. 1;

FIG. 3 is a perspective view of the magnetoresistive memory cell of FIG. 2;

FIGS. 4 and 5 are diagrams for explaining a write operation of a magnetic tunnel junction (MTJ) layer constituting the magnetoresistive memory cell of FIG. 1;

FIGS. 6A to 6E are diagrams showing an MTJ constituting the magnetoresistive memory cell of FIG. 1, according to various embodiments;

FIG. 7 is a plan view for explaining a variable resistance memory device according to at least one embodiment;

FIG. 8 is a partial circuit diagram showing a variable resistance memory device according to at least one embodiment;

FIG. 9 is a cross-sectional view of a variable resistance memory device taken along a line A-A′ of FIG. 8;

FIG. 10 is a partially enlarged cross-sectional view of FIG. 9;

FIG. 11 is a partial circuit diagram showing a variable resistance memory device according to at least one embodiment;

FIG. 12 is a cross-sectional view of a variable resistance memory device taken along a line B-B′ of FIG. 11;

FIG. 13 is a partially enlarged cross-sectional view of FIG. 12;

FIG. 14 is a partial circuit diagram showing a variable resistance memory device according to at least one embodiment;

FIG. 15 is a cross-sectional view of a variable resistance memory device taken along a line C-C′ of FIG. 14;

FIG. 16 is a partially enlarged cross-sectional view of FIG. 15;

FIG. 17 is a configuration diagram showing a variable resistance memory device according to at least one embodiment;

FIG. 18 is a configuration diagram of a data processing system including a variable resistance memory device according to at least one embodiment; and

FIG. 19 is a configuration diagram of a data processing system including a variable resistance memory device according to at least one embodiment.

### DETAILED DESCRIPTION OF THE EMBODIMENTS

Hereinafter, the technical spirit of the inventive concepts is described in detail with reference to the attached drawings. The following embodiments may be implemented by one of the embodiments or implemented by combining one or more of the embodiments. Accordingly, the technical spirit of the inventive concepts needs not be construed as being limited to one embodiment. Components expressed in the singular herein may include plural numbers.

Additionally, in the present specification, functional elements and/or device, including units that have and/or configured to have at least one function or operation such a “ . . . device”, “processor”, “module”, “controller”, “ . . . unit”, etc., may be implemented with processing circuitry including hardware, software, or a combination of hardware and software. For example, the processing circuitry more specifically may include, but is not limited to, a central processing unit (CPU), a neural processing unit (NPU), a graphics processing unit (GPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

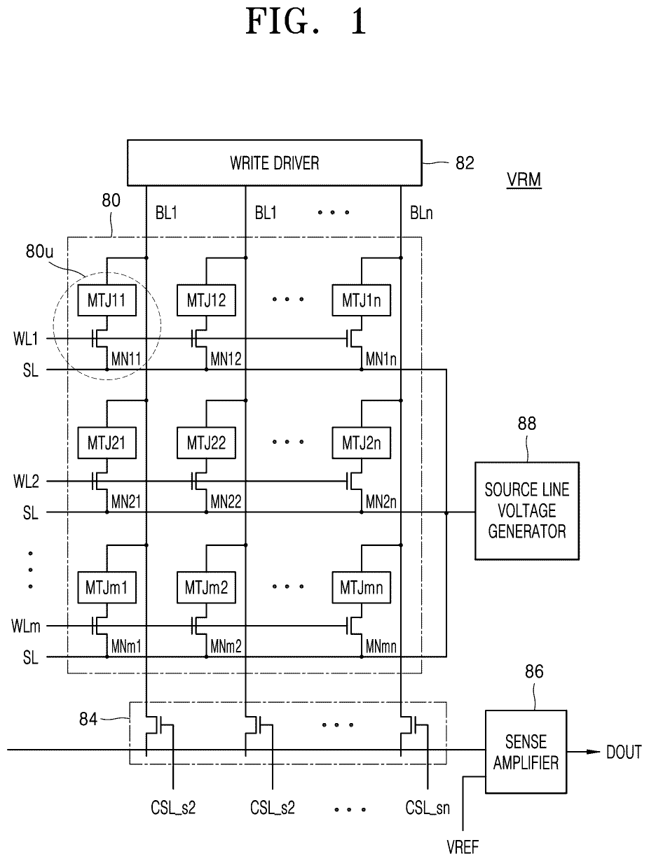

FIG. 1 is a circuit diagram showing a cell array of a variable resistance memory device according to at least one embodiment.

In the at least one embodiment, an example of a variable resistance memory device VRM may be a magnetoresistive memory device. The magnetoresistive memory device may include magnetoresistive random access memory (MRAM). The variable resistance memory device VRM may include at least one variable resistance layer, that is, at least one magnetic tunnel junction (MTJ) layer (or MTJ pattern).

For example, in at least one embodiment, the variable resistance memory device VRM includes a magnetoresistive memory cell array 80. The magnetoresistive memory cell array 80 may also be referred to as a memory cell array (or cell array). The magnetoresistive memory cell array 80 may be connected to a write driver 82, a selection circuit 84, a source line voltage generator 88, and a sense amplifier 86.

The magnetoresistive memory cell array 80 may include a plurality of magnetoresistive memory cells 80u. The magnetoresistive memory cells 80u may also be simply referred to as memory cells. The magnetoresistive memory cell array 80 may include a plurality of word lines WL1 to WLm and a plurality of bit lines BL1 to BLn. The magnetoresistive memory cell array 80 may have the magnetoresistive memory cell 80u between each of the word lines WL1 to WLm and a corresponding one of the bit lines BL1 to BLn.

Each of the magnetoresistive memory cells 80 may include one of a plurality of cell transistors MN11 to MNmn (having gates connected to the word lines WL1 to WLm), and a corresponding one of a plurality of MTJ layers MTJ11 to MTJmn (connected between each of the cell transistors MN11 to MNmn and each of the bit lines BL1 to BLn), with the MTJ layers MTJ11 to MTJmn constituting a variable resistance layer.

Respective sources of cell transistors MN11 to MNIn may be connected to a source line SL. The selection circuit 84 may be configured to selectively connect the bit lines BL1 to BLn to the sense amplifier 86 in response to column selection signals CSL_s1 to CSL_sn. The sense amplifier 86 may be configured to generate output data DOUT by amplifying a difference between an output voltage signal of the selection circuit 84 and a reference voltage VREF.

The write driver 82 may be connected to the bit lines BL1 to BLn, and may be configured to generate a program current based on write data, and to provide the program current to the bit lines BL1 to BLn. As described in further detail below, to magnetize the MTJ layers MTJ11 to MTJmn in the magnetoresistive memory cell array 80, a voltage higher than the voltage applied to the bit lines BL1 to BLn may be applied to the source line SL. The source line voltage generator 88 may generate a source line driving voltage VSL and provide the source line driving voltage VSL to source lines of the magnetoresistive memory cell array 80.

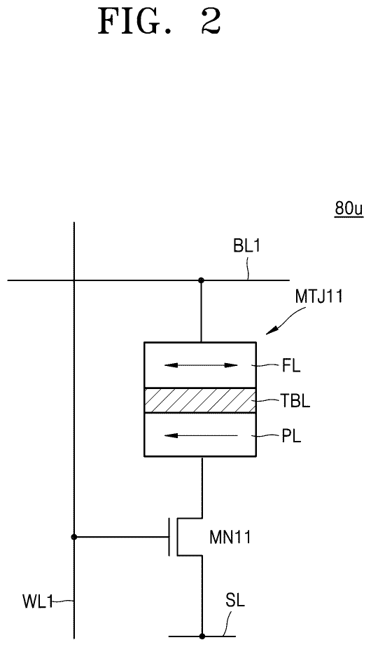

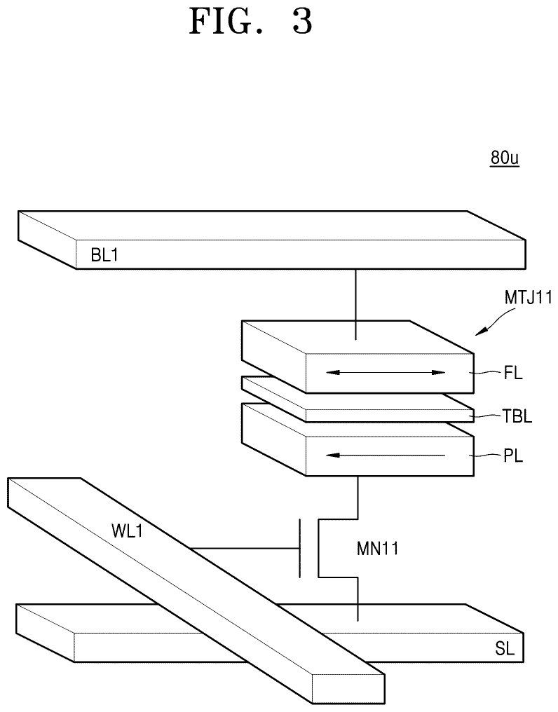

FIG. 2 is a circuit diagram showing the magnetoresistive memory cell of FIG. 1, and FIG. 3 is a perspective view of the magnetoresistive memory cell of FIG. 2.

In detail, as shown in FIGS. 2 and 3, the magnetoresistive memory cell 80u may include a cell transistor MN11 (including, e.g., an n-type metal-oxide-semiconductor (NMOS) transistor) and an MTJ layer MTJ11. In at least one embodiment, the cell transistor MN11 has a gate connected to the word line WL1 and a source connected to the source line SL; and the MTJ layer MTJ11 is connected between a drain of the cell transistor MN11 and the bit line BL1.

Further, as shown in FIGS. 2 and 3, the MTJ layer MTJ11 may include a pinned layer PL having a fixed magnetization direction, a free layer FL configured to be magnetized in a direction of a magnetic field applied from the outside, and a tunnel barrier layer TBL formed as an insulating layer between the pinned layer PL and the free layer FL.

In some embodiments, the pinned layer PL may include iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), iron (Fe), nickel (Ni), cobalt (Co), ruthenium (Ru), iridium (Ir), rhodium (Rh), and/or the like.

In some embodiments, the tunnel barrier layer TBL may include aluminum oxide or magnesium oxide.

In some embodiments, the free layer FL may be a ferromagnetic material including at least one of iron (Fe), nickel (Ni), and cobalt (Co).

The MTJ layer MTJ11 of FIG. 3 may be provided in a cell constituting spin transfer torque (STT)-MRAM. To perform a write operation of the STT-MRAM, a logic high voltage may be applied to the word line WL1 to turn on the cell transistor MN11, and a write current may be applied between the bit line BL1 and the source line SL.

To perform a read operation of the STT-MRAM, a logic high voltage may be applied to the word line WL1 to turn on the cell transistor MN11, and then a read current may be applied from the bit line BL1 toward the source line SL to identify data stored in the magnetoresistive memory cell 80u depending on a resistance value of the MTJ layer MTJ11 with respect to the read current.

The resistance value of the MTJ layer MTJ11 varies depending on the magnetization direction of the free layer FL. For example, in the MTJ layer MTJ11, the magnetization direction of the free layer FL and the magnetization direction of the pinned layer PL may be arranged in parallel to each other. In this case, the MTJ layer MTJ11 may have a “low” resistance value and read data ‘0’; and/or, in the MTJ layer MTJ11, the magnetization direction of the free layer FL and the magnetization direction of the pinned layer PL may be arranged in antiparallel to each other. In this case, the MTJ layer MTJ11 may have a “high” resistance value and read data ‘1’. In other words, data may be stored in the (STT)-RAM based on the relative resistance values between the parallel and anti-parallel states of the MTJ layer MTJ11. In this case, the relative resistance values may be used to represent binary data (e.g., ‘0’ and ‘1’) for a binary operation, and/or, in at least one embodiment, the relative resistance values may be used to represent analog data (e.g., a range between ‘0’ and ‘1’) for an analog operation.

FIGS. 2 and 3 shows a horizontal magnetic in which the magnetization directions of the free layer FL and the pinned layer PL of the MTJ layer MTJ11 are horizontal, but as will be described later, in other embodiments, a vertical magnetic device in which the magnetization directions of the free layer FL and the pinned layer PL are vertical may also be used.

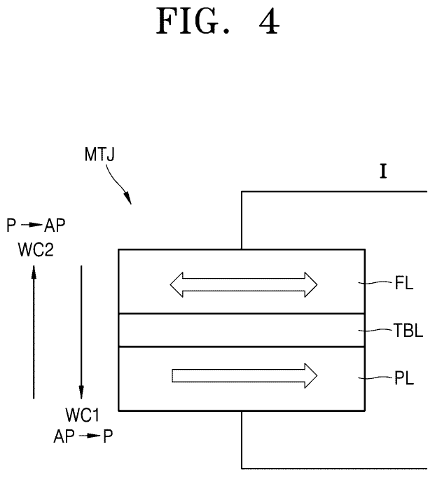

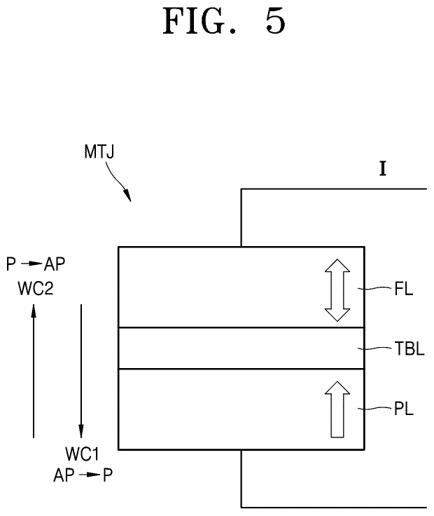

FIGS. 4 and 5 are diagrams for explaining a write operation of an MTJ layer constituting the magnetoresistive memory cell of FIG. 1.

In detail, FIG. 4 shows a horizontal magnetic device in which the magnetization directions of the free layer FL and the pinned layer PL of the MTJ layer are horizontal. In an MTJ layer with horizontal magnetization directions, the direction of current movement and the easy axis of magnetization may be substantially vertical. FIG. 5 shows a case of a vertical magnetic device in which the magnetization directions of the free layer FL and the pinned layer PL are vertical. In an MTJ layer with vertical magnetization directions, the direction of current movement and the easy axis of magnetization may be substantially horizontal.

The magnetization direction of the free layer FL may be determined depending on the direction of the write currents WC1 and WC2 flowing in the MTJ layer. For example, when the first write current WC1 is applied, free electrons having the same spin direction as the pinned layer PL may apply torque to the free layer FL. Accordingly, the free layer FL may be magnetized in parallel (P) to the pinned layer PL.

When the second write current WC2 is applied, electrons having a spin opposite to that of the pinned layer PL return to the free layer FL and apply torque. Accordingly, the free layer FL may be magnetized in antiparallel (AP) to the pinned layer PL. That is, the magnetization direction of the free layer FL in the MTJ layer may be changed by spin transfer torque STT.

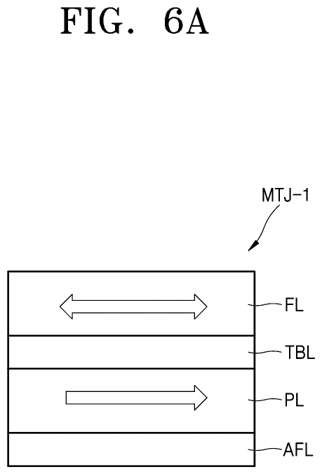

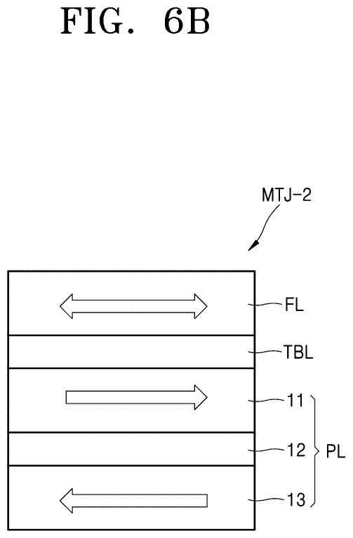

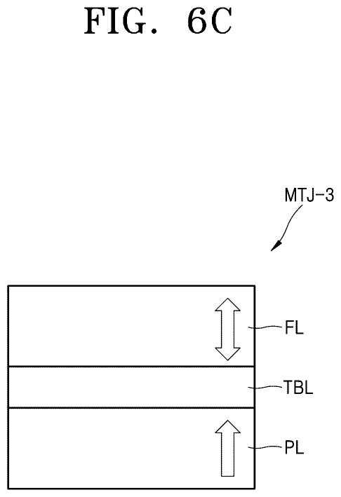

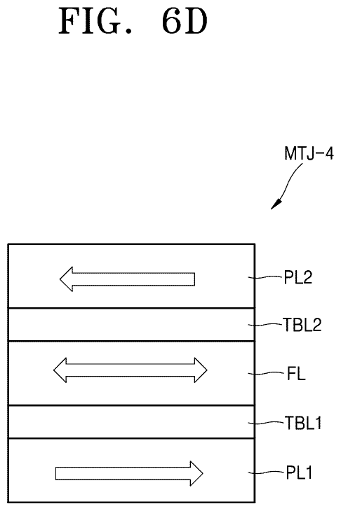

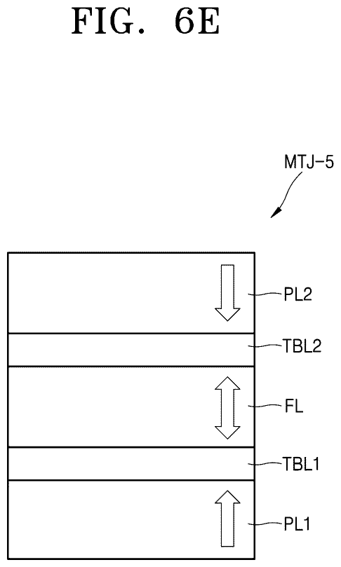

FIGS. 6A to 6E are diagrams showing an MTJ constituting the magnetoresistive memory cell of FIG. 1, according to various embodiments.

Referring to FIG. 6A, an MTJ layer MTJ-1 may include a free layer FL, a tunnel barrier layer TBL, a pinned layer PL, and an antiferromagnetic layer AFL. The MTJ layer MTJ-1 may include a single MTJ layer. As illustrated above, in at least one embodiment, the antiferromagnetic layer AFL may not be provided (e.g., may be omitted). The free layer FL may include a material having a changeable magnetization direction. For example, the magnetization direction of the free layer FL may be changed by electrical/magnetic factors provided outside and/or inside the magnetoresistive memory cell.

The free layer FL may include a ferromagnetic material containing at least one of cobalt (Co), iron (Fe), and/or nickel (Ni). For example, the free layer FL may include at least one selected from FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂.

The tunnel barrier layer TBL may have a thickness thinner than a spin diffusion distance. The tunnel barrier layer TBL may include a non-magnetic material. For example, the tunnel barrier layer TBL may include at least one selected from oxides of magnesium (Mg), titanium (Ti), aluminum (Al), magnesium-zinc (MgZn), and magnesium-boron (MgB), and nitrides of titanium (Ti) and/or vanadium (V).

In at least one embodiment, the pinned layer PL may include a ferromagnetic material. For example, the pinned layer PL may include a ferromagnetic phase of at least one selected from CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂. In at least one embodiment, the material phase of the pinned layer PL and the free layer FL may be different to each other, e.g., in embodiments wherein the pinned layer PL and the free layer FL include the same and/or similar material compositions. In addition, in at least some embodiments, the magnetization direction of the pinned layer PL may be fixed (or ‘pinned’) by the antiferromagnetic layer AFL.

The anti-ferromagnetic layer AFL may include an anti-ferromagnetic material. For example, the antiferromagnetic layer AFL may include at least one selected from PtMn, IrMn, MnO, MnS, MnTe, MnF₂, FeCl₂, FeO, CoCl₂, CoO, NiCl₂, NiO, and/or Cr having an anti-ferromagnetic material phase.

Referring to FIG. 6B, the pinned layer PL of an MTJ layer MTJ-2 is provided as a synthetic anti ferromagnetic (SAF). The pinned layer PL may include a first ferromagnetic layer 11, a coupling layer 12, and a second ferromagnetic layer 13. The first and second ferromagnetic layers 11 and 13 may include a ferromagnetic phase of at least one selected from CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂. In this case, the magnetization direction of the first ferromagnetic layer 11 and the magnetization direction of the second ferromagnetic layer 13 may be different from each other, and each magnetization direction may be fixed such that the pinned layer PL has fixed average magnetization direction. In at least one embodiment, the coupling layer 12 may include ruthenium (Ru).

Referring to FIG. 6C, an MTJ layer MTJ-3 may be a single MTJ layer. To implement the MTJ layer MTJ-3 with a vertical magnetization direction, the free layer FL and the pinned layer PL may include a material with high magnetic anisotropy energy. Materials with high magnetic anisotropy energy may include a multilayer thin film such as amorphous rare earth element alloys, (Co/Pt) n, or (Fe/Pt) n.

For example, the free layer FL may include an ordered alloy and include at least one of iron (Fe), cobalt (Co), nickel (Ni), palladium (Pa), and platinum (Pt). For example, the free layer FL may include at least one of Fe—Pt alloy, Fe—Pd alloy, Co—Pd alloy, Co—Pt alloy, Fe—Ni—Pt alloy, Co—Fe—Pt alloy, and Co—Ni—Pt alloy. The alloys may be represented as Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀, for example, in chemical quantitative terms.

The pinned layer PL may include an ordered alloy and include at least one of iron (Fe), cobalt (Co), nickel (Ni), palladium (Pa), and platinum (Pt). For example, the pinned layer PL may include at least one of Fe—Pt alloy, Fe—Pd alloy, Co—Pd alloy, Co—Pt alloy, Fe—Ni—Pt alloy, Co—Fe—Pt alloy, and Co—Ni—Pt alloy. The alloys may be represented as FesoPt₅₀, FesoPd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀, for example, in chemical quantitative terms. In at least one embodiment, the ordered alloy of the pinned layer PL may be selected to have a higher magnetic anisotropy energy compared to the ordered alloy selected for the free layer FL.

Referring to FIGS. 6D and 6E, FIGS. 6D and 6E are diagrams showing dual MTJ layers MTJ-4 and MTJ-5. The dual MTJ layers MTJ-4 and MTJ-5 have a structure in which tunnel barrier layers TBL1 and TBL2 and pinned layers PL1 and PL2 are located at both ends of the free layer FL, respectively.

Referring to FIG. 6D, the dual MTJ layer MTJ-4 forming horizontal magnetism may include a first pinned layer PL2, a first tunnel barrier layer TBL2, a free layer FL, a second tunnel barrier layer TBL1, and a second pinned layer PL1.

Materials constituting each layer may be the same as and/or substantially similar to the free layer FL, the tunnel barrier layer TBL, and the pinned layer PL of FIG. 6A described above. When the magnetization direction of the first pinned layer PL2 and the magnetization direction of the second pinned layer PL1 are fixed in opposite directions, magnetic forces caused by the first and second pinned layers PL1 and PL2 are substantially canceled out.

Therefore, the dual MTJ layer MTJ-4 may perform a write operation by using less current than the single MTJ layer MTJ-1. Due to the second tunnel barrier layer TBL1, the dual MTJ layer MTJ-4 provides higher resistance during a read operation, and thus a clear data value may be obtained. Additionally, when the magnetization direction of the free layer FL is applied in either the parallel and/or anti-parallel direction of either the first pinned layer PL2 and/or the second pinned layer PL1, the resistance of the dual MTJ layer MTJ-4 may increase.

Referring to FIG. 6E, the dual MTJ layer MTJ-5 forming vertical magnetism may include the first pinned layer PL2, the first tunnel barrier layer TBL2, the free layer FL, the second tunnel barrier layer TBL1, and the second pinned layer PL1. Materials constituting each layer may be the same as or similar to the free layer FL, the tunnel barrier layer TBL, and the pinned layer PL of FIG. 6C described above. When the magnetization direction of the first pinned layer PL2 and the magnetization direction of the second pinned layer PL1 are fixed in opposite directions, magnetic forces caused by the first and second pinned layers PL1 and PL2 are substantially canceled out. Therefore, the dual MTJ layer MTJ-5 may perform a write operation by using less current than the single MTJ layer MTJ-3.

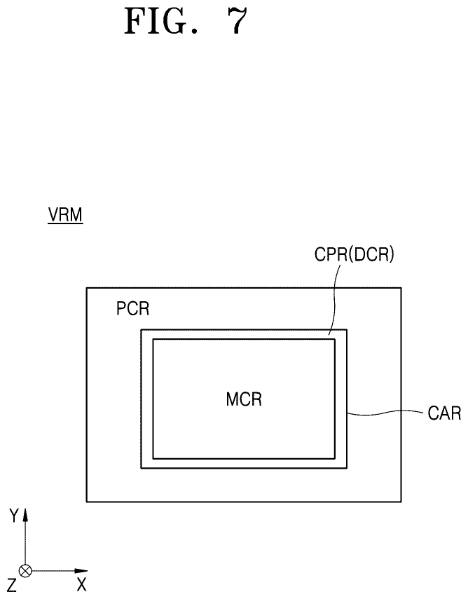

FIGS. 7 to 16 described below illustrate in detail an implementation example of a magnetoresistive memory device as a variable resistance memory device according to the technical spirit of the inventive concepts. In the following drawings, a first direction (X direction) may be a row direction, and a second direction (Y direction) may be a column direction. A third direction (Z direction) may be a vertical direction perpendicular to a plane defined by the first direction (X direction) and the second direction (Y direction). However, it will also be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly.

FIG. 7 is a plan view for explaining a variable resistance memory device according to at least one embodiment.

In detail, the variable resistance memory device VRM may be a magnetoresistive memory device. The variable resistance memory device VRM may include a cell array region CAR and a peripheral circuit region PCR surrounding the cell array region CAR.

The cell array region CAR may include a region in which a memory cell array (e.g., the magnetoresistive memory cell array 80) is located. For example, the cell array region CAR may include a region in which the magnetoresistive memory cells 80u are located.

The cell array region CAR may include a main cell region MCR in which the magnetoresistive memory cells 80u of FIGS. 1 and 2, that is, memory cells (or active cells) are located and a cell peripheral region CPR which is outside the main cell region MCR and in which dummy cells are located.

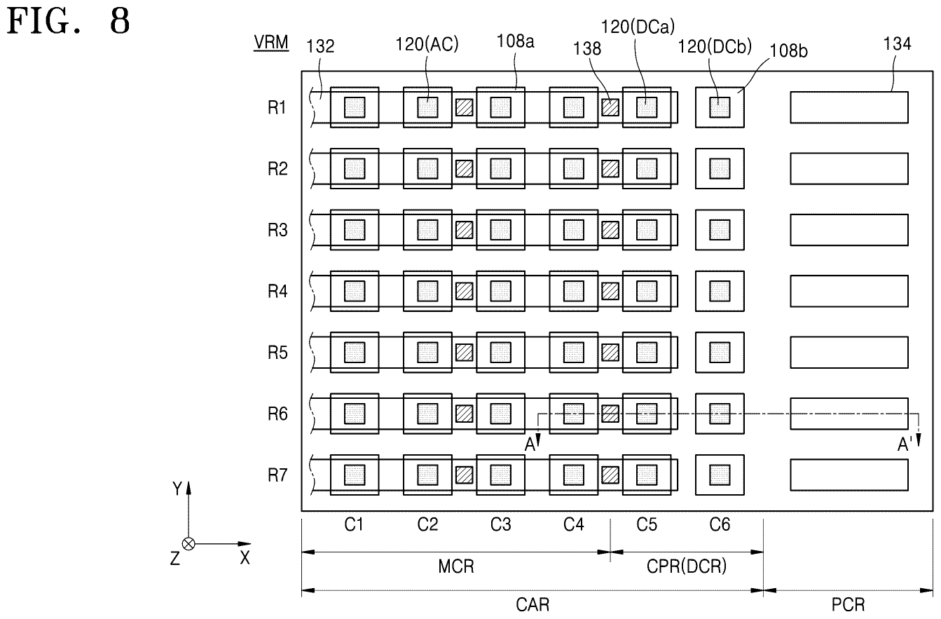

The dummy cells, for example, dummy cells DCa and DCb of FIGS. 8 to 10, may refer to a cell that performs a write operation differently from the memory cells 80 (in FIG. 1) described with reference to FIGS. 1 to 6E and/or does not perform a read operation of reading memory cells on which the write operation is performed. A concept opposite to dummy cells may be active cells. The active cell may refer to a cell that performs a write operation or performs a read operation of reading memory cells on which the write operation is performed, differently from the dummy cells, for example, the dummy cells DCa and DCb of FIGS. 8 to 10.

The peripheral circuit region PCR may include a region in which peripheral circuits controlling the cell array region CAR or a peripheral transistor are located. The peripheral circuit region PCR may be a region in which core/ferry circuits are arranged.

The cell array region CAR may include the cell peripheral region CPR located between the cell array region CAR and the peripheral circuit region PCR. The cell peripheral region CPR may be a region surrounding the main cell region MCR. The peripheral circuit region PCR may be a region surrounding the cell peripheral region CPR.

The cell peripheral region CPR may include a dummy cell region DCR in which dummy cells resulting from a manufacturing process (for example, the dummy cells DCa and DCb of FIGS. 8 to 10) are located. As described below, when first cell wiring lines 132 (in FIG. 8) extend long in the first direction (X direction, row direction) and are apart from each other in the second direction (Y direction, column direction), dummy cells, for example, the dummy cells DCa and DCb of FIGS. 8 to 10, may be formed in the second direction (Y direction, column direction).

FIG. 8 is a partial circuit diagram showing a variable resistance memory device according to at least one embodiment.

In detail, the variable resistance memory device VRM may include the cell array region CAR and the peripheral circuit region PCR as shown in FIG. 7. In the cell array region CAR, a plurality of memory cells AC, DCa, and DCb may be spaced apart from each other in the first direction (X direction, row direction) and a second direction (Y direction, column direction) perpendicular to the first direction (X direction, row direction).

The cell array region CAR may include the main cell region MCR in which active cells AC of the memory cells AC, DCa, and DCb are located and the cell peripheral region CPR which is outside the main cell region MCR and in which the dummy cells DCa and DCb are located in N columns (N is a natural number greater than or equal to 2), for example, two columns C5 and C6 of the memory cells AC, DCa, and DCb.

In some embodiments, the dummy cells DCa and DCb may include first dummy cells DCa and second dummy cells DCb. The first dummy cells DCa may be located in one column C5, and the second dummy cells DCb may be located in one column C6. In some embodiments, unlike FIG. 8, the first dummy cells DCa may be arranged in two or more columns, and the second dummy cells DCb may also be arranged in two or more columns. As a result, the first dummy cells DCa and the second dummy cells DCb may be arranged in at least two or more columns.

The peripheral circuit region PCR may be located on one side of the cell array region CAR. The cell array region CAR may include the cell peripheral region CPR located between the main cell region MCR and the peripheral circuit region PCR. The cell peripheral region CPR may include the dummy cell region DCR in which the dummy cells DCa and DCb required for a manufacturing process are located.

The partial layout shown in FIG. 8 illustrates a portion of the variable resistance memory device VRM. In some embodiments, the peripheral circuit region PCR may be located to the right of the cell array region CAR in the first direction (X direction, row direction). In some embodiments, the peripheral circuit region PCR may be located to the left of the cell array region CAR in the first direction (X direction) differently from FIG. 8.

In some embodiments, as shown in FIG. 8, the cell peripheral region CPR, that is, the dummy cell region DCR, may be located to the right of the cell array region CAR in the first direction (X direction, row direction). In some embodiments, differently from FIG. 8, the cell peripheral region CPR, that is, the dummy cell region DCR, may be located to the left of the cell array region CAR in the first direction (X direction, row direction).

The variable resistance memory device VRM may include variable resistance pattern structures 120 that are regularly arranged apart from each other in the first direction (X direction, row direction) and the second direction (Y direction, column direction). E (E is a natural number greater than or equal to 1) variable resistance pattern structures 120 may be arranged in the first direction (X direction, row direction), and F (F is a natural number greater than or equal to 1) variable resistance pattern structures 120 may be arranged in the second direction (Y direction, column direction).

For convenience, FIG. 8 shows 7×6 matrix arrangement in which seven variable resistance pattern structures 120 of R1 to R7 are arranged in the first direction (X direction, row direction) and six variable resistance pattern structures 120 of C1 to C6 are arranged in the second direction (Y direction, column direction), in the cell array region CAR, however the example embodiments are not limited thereto.

The variable resistance pattern structures 120 may include the memory cells AC, DCa, and DCb. In the variable resistance pattern structures 120, the memory cells AC located in the main cell region MCR may include active cells. In the variable resistance pattern structures 120, the memory cells DCa and DCb, located in the cell peripheral region CPR and the dummy cell region DCR, may include dummy cells.

The variable resistance pattern structures 120 may be located on first contact plugs 108a and 108b. The first contact plugs 108a and 108b may include a cell contact plug 108a located in the cell array region CAR and a dummy cell contact plug 108b located in the dummy cell region DCR.

The variable resistance pattern structures 120 may include a variable resistance layer (e.g., a MTJ layer and/or a MTJ pattern). The variable resistance pattern structures 120 located in the cell array region CAR may include the active cells AC that perform a write operation and a read operation. The variable resistance pattern structures 120 located in the cell peripheral region CPR, that is, the dummy cell region DCR, may include the dummy cells DCa and DCb that do not perform a write operation and a read operation.

According to the inventive concepts, in the cell peripheral region CPR, that is, the dummy cell region DCR located outside the main cell region MCR in the second direction (Y direction, column direction), dummy cells, for example, DCa and DCb may be located in N columns (N is a natural number greater than or equal to 2), for example, the columns C5 and C6. In some embodiments, as shown in FIG. 8, in the cell peripheral region CPR, that is, the dummy cell region DCR located outside the main cell region MCR in the second direction (Y direction, column direction), the dummy cells DCa and DCb may be located in the two columns C5 and C6.

The dummy cells DCa and DCb provided in the cell peripheral region CPR may be introduced to improve process reliability (e.g., manufacturing process reliability) of the variable resistance memory device VRM. For example, the dummy cells DCa and DCb provided in the cell peripheral region CPR may be introduced to improve the reliability of a chemical mechanical polishing process and/or an etching process when the variable resistance memory device VRM is manufactured.

In the variable resistance memory device VRM, the first cell wiring lines 132 may extend long in the first direction (X direction, row direction) on the variable resistance pattern structures 120. The first cell wiring lines 132 may be arranged apart from each other in the second direction (Y direction, column direction).

In some embodiments, differently from FIG. 8, the first cell wiring lines 132 may extend long in the second direction (Y direction, column direction) on the variable resistance pattern structures 120 and may be apart from each other in the in the first direction (X direction, row direction).

The first cell wiring lines 132 may be arranged to extend from the cell array region CAR to a portion of the cell peripheral region CPR in the first direction (X direction, row direction). In some embodiments, the first cell wiring lines 132 may extend on the first dummy cells DCa of the cell peripheral region CPR from the cell array region CAR in the first direction (X direction, row direction). The first cell wiring lines 132 may extend on one of the two columns C5 and C6 constituting the dummy cells DCa and DCb from the cell array region CAR in the first direction (X direction).

The first cell wiring lines 132 may not extend on the outermost portion of the two columns C5 and C6 constituting the dummy cells DCa and DCb of the cell peripheral region CPR from the cell array region CAR in the first direction (X direction). The first cell wiring lines 132 does not extend in the first direction (X direction, row direction) from the cell array region CAR to the second dummy cells DCb, which are the outermost portion of the cell peripheral region CPR.

In other words, from among the dummy cells DCa and DCb, the first dummy cells DCa located in at least one column adjacent to the main cell region MCR, for example, C1 to C4, are connected to the first cell wiring lines 132. From among the dummy cells DCa and DCb, the second dummy cells DCb located in at least one column adjacent to the peripheral circuit region PCR, for example, C5 to C6, are not connected to the first cell wiring lines 132.

The variable resistance memory device VRM includes first peripheral wiring lines 134 extending in the first direction (X direction, row direction). The first peripheral wiring lines 134 may be arranged apart from each other in the second direction (Y direction, column direction). The first peripheral wiring lines 134 may be placed at the same level as the first cell wiring lines 132.

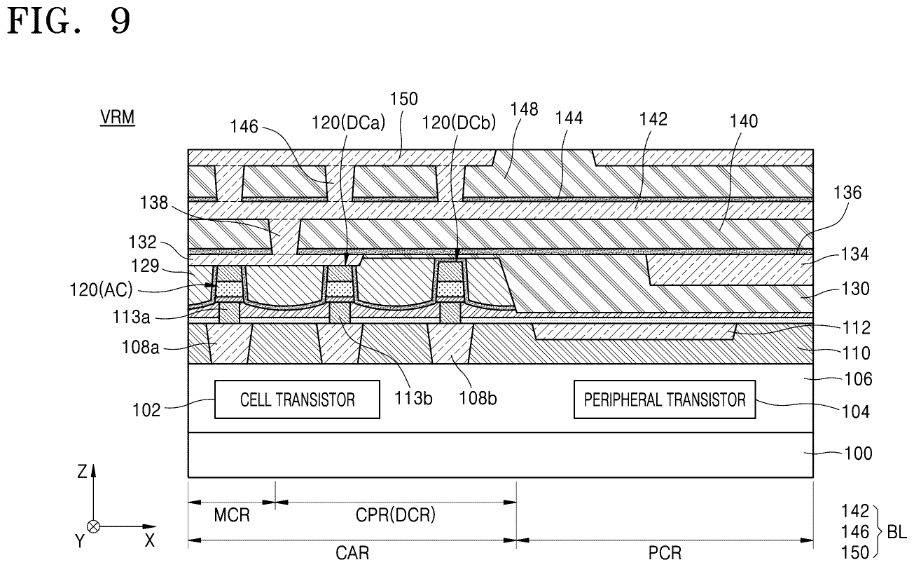

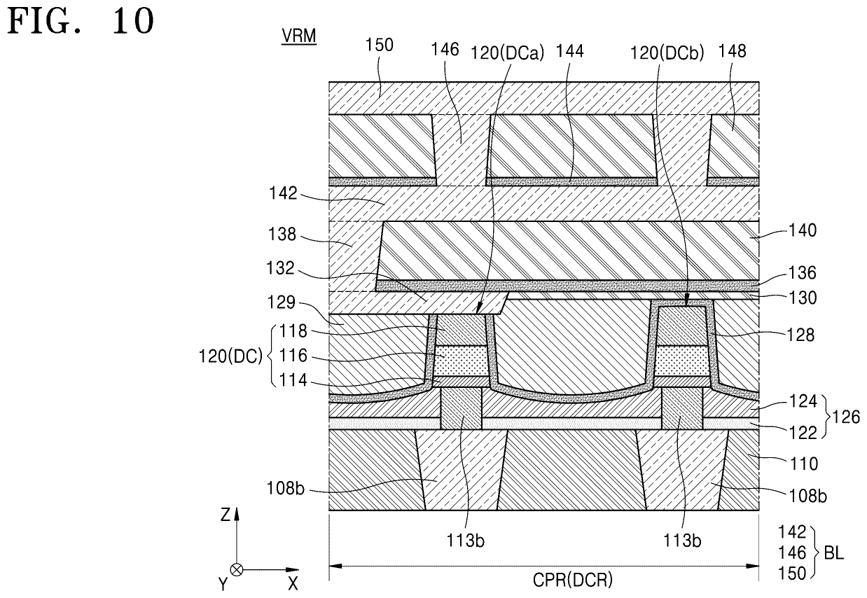

The first peripheral wiring lines 134 may not be connected to the first cell wiring lines 132. The cell array region CAR may include second contact plugs 138 connecting the first cell wiring lines 132 to bit lines BL (in FIGS. 9 and 10). Like the first cell wiring lines 132, the bit lines BL (in FIGS. 9 and 10) may extend long in the first direction (X direction, row direction) and may be arranged apart from each other in the second direction (Y direction, column direction).

The first cell wiring lines 132 does not extend in the first direction (X direction, row direction) from the cell array region CAR to the second dummy cells DCb, which are the outermost portion of the cell peripheral region CPR. Accordingly, the generation of metal foreign substances in the main cell region MCR is prevented (or mitigated) during a photoetching process for forming the first cell wiring lines 132. As a result, in the variable resistance memory device VRM, occurrence of short circuit defects in the second direction (Y direction) due to metal foreign substances may be suppressed in the bit lines BL (in FIGS. 9 and 10) connected to the first cell wiring lines 132.

FIG. 9 is a cross-sectional view of a variable resistance memory device taken along a line A-A′ of FIG. 8, and FIG. 10 is a partially enlarged cross-sectional view of FIG. 9.

In detail, the variable resistance memory device VRM may include a substrate 100 divided into the cell array region CAR and the peripheral circuit region PCR. The cell array region CAR may be a region in which memory cells are formed. The cell array region CAR may include the main cell region MCR, and the dummy cell region DCR located on one side of the main cell region MCR.

In the cell array region CAR, the cell peripheral region CPR may be located between the main cell region MCR and the peripheral circuit region PCR. The cell peripheral region CPR may include the dummy cell region DCR in which the dummy cells DCa and DCb are located. The peripheral circuit region PCR may be located around the cell array region CAR, for example, on one side of the cell array region CAR, and may be a region in which core/ferry circuits are formed.

A cell transistor 102 may be formed on the substrate 100 in the cell array region CAR. In at least one embodiment, the cell transistor 102 may include a buried gate type transistor. A peripheral transistor 104 may be formed on the substrate 100 in the peripheral circuit region PCR. The peripheral transistor 104 may include a planar type transistor. A level at which the cell transistor 102 and the peripheral transistor 104 are formed may be referred to as a transistor level layer 106.

The cell contact plugs 108a connected to the cell transistor 102 are formed on the main cell region MCR on the transistor level layer 106. A plurality of dummy cell contact plugs 108b that are not connected to the cell transistor 102 are located in the dummy cell region DCR on the transistor level layer 106. The cell contact plugs 108a and the dummy cell contact plugs 108b constitute first contact plugs 108a and 108b.

A first peripheral wiring layer 112 connected to the peripheral transistor 104 may be located in the peripheral circuit region PCR on the transistor level layer 106. The first contact plugs 108a and 108b and the first peripheral wiring layer 112 may be insulated by a first interlayer insulating layer 110.

Pad electrodes 113a and 113b may be located on the first contact plugs 108a and 108b in the cell array region CAR. The pad electrodes 113a and 113b may include cell pad electrodes 113a and dummy cell pad electrodes 113b. The cell pad electrodes 113a may be located on the cell contact plugs 108a. The dummy cell pad electrodes 113b may be located on the dummy cell contact plugs 108b.

A pad separation insulating layer 126 may be provided between the pad electrodes 113a and 113b and on the first interlayer insulating layer 110 and the first peripheral wiring layer 112. The pad separation insulating layer 126 may be a dual pad separation insulating layer.

The pad separation insulating layer 126 may include a first pad separation insulating layer 122 and a second pad separation insulating layer 124 formed on the first pad separation insulating layer 122. In at least one embodiment, the first pad separation insulating layer 122 and the second pad separation insulating layer 124 may include different materials.

In some embodiments, the first pad separation insulating layer 122 may include a material with a lower dielectric constant than that of a silicon oxide layer. For example, the first pad separation insulating layer 122 may include a material having a low dielectric constant (k value) less than 3.9, for example, an ultra-low-k (ULK) dielectric, a low-k (LK) dielectric, or an extreme low-k (ELK) dielectric.

In some embodiments, the first pad separation insulating layer 122 may include a material containing Si, O, and C. In some embodiments, the first pad separation insulating layer 122 may include a SiOC film, a SiOF film, a SiCH film, a SiOCH film, or a combination thereof. The second pad separation insulating layer 124 may include a silicon oxide layer. Since capacitance is related to the intensity of the dielectric constant, when the first pad separation insulating layer 122 includes a material having a low dielectric constant, parasitic capacitance between the pad electrodes 113a and 113b may be reduced.

The pad electrodes 113a and 113b may be located where direct contact between the first contact plugs 108a and 108b and the variable resistance pattern structure 120 is difficult. Therefore, when the first contact plugs 108a and 108b are arranged to be in direct contact with the variable resistance pattern structures 120, the pad electrodes 113a and 113b may not be provided.

The variable resistance pattern structure 120 constituting a memory cell may be provided on the pad electrodes 113a and 113b. The variable resistance pattern structure 120 may have a structure in which a lower electrode 114, a MTJ pattern 116, and an upper electrode 118 are stacked. The MTJ pattern 116 may constitute a variable resistance layer and, as described above, may include the pinned layer PL, the tunnel barrier layer TBL, and the free layer FL. The lower electrode 114 and upper electrode 118 may include metal or metal nitride.

The variable resistance pattern structure 120 located in the cell array region CAR may constitute the active cells AC. The active cells AC may be located on cell contact plugs 108a. The active cells AC may be connected to the cell contact plugs 108a through the cell pad electrodes 113a. The active cells AC may perform a write operation and a read operation.

The dummy cells DCa and DCb that do not perform a write operation and a read operation may be located in the variable resistance pattern structures 120 located in the cell peripheral region CPR, that is, the dummy cell region DCR. The dummy cells DCa and DCb may be located on the dummy cell contact plugs 108b. The dummy cells DCa and DCb may be connected to the dummy cell contact plugs 108b through the dummy cell pad electrodes 113b. For example, in at least some embodiment, the dummy cell pad electrodes 113b may not be connected to a cell transistor 102.

The dummy cells DCa and DCb may include at least one first dummy cell DCa located adjacent to the main cell region MCR and at least one second dummy cell DCb located adjacent to the peripheral circuit region PCR.

A capping layer pattern 128 may be formed on a surface of the pad separation insulating layer 126 while covering a sidewall of the variable resistance pattern structure 120. The capping layer pattern 128 may be provided to protect the variable resistance pattern structure 120. The capping layer pattern 128 may include an insulating material. The capping layer pattern 128 may include, for example, a silicon nitride layer.

A buried layer pattern 129 may be formed on the capping layer pattern 128 and may fill at least a portion of the space between the variable resistance pattern structures 120. In at least one embodiment, the buried layer pattern 129 may fill the space between the variable resistance pattern structures 120 without voids. The buried layer pattern 129 may be located in the buried layer pattern 129 and may not be located in the peripheral circuit region PCR.

In some embodiments, the buried layer pattern 129 may include a silicon oxide layer and/or a silicon nitride layer. In some embodiments, the buried layer pattern 129 may include a material with a lower dielectric constant than that of a silicon oxide layer. The buried layer pattern 129 may include a material having a low dielectric constant (k value) less than 3.9, for example, an ultra-low-k (ULK) dielectric, a low-k (LK) dielectric, or an extreme low-k (ELK) dielectric.

In some embodiments, the buried layer pattern 129 may include a material containing Si, O, and C. In some embodiments, the buried layer pattern 129 may include a SiOC film, a SiOF film, a SiCH film, a SiOCH film, or a combination thereof. When the buried layer pattern 129 includes a material having a low dielectric constant, parasitic capacitance between the variable resistance pattern structures 120 may be reduced.

A step difference may be formed between the cell array region CAR and the peripheral circuit region PCR due to the variable resistance pattern structure 120. A second interlayer insulating layer 130 may be formed on the pad separation insulating layer 126 in the peripheral circuit region PCR to offset the step between the cell array region CAR and the peripheral circuit region PCR.

In some embodiments, the second interlayer insulating layer 130 may include the same material as the buried layer pattern 129. In some embodiments, the second interlayer insulating layer 130 may include a material having a low dielectric constant used in the buried layer pattern 129. In some embodiments, the second interlayer insulating layer 130 may include a material with a lower dielectric constant than that of a silicon oxide layer.

A first cell wiring line 132 may be located on the active cells AC and the first dummy cell DCa in the variable resistance pattern structures 120. The first cell wiring line 132 may be located on the upper electrode 118 of the variable resistance pattern structures 120. The first cell wiring line 132 may be located in a portion of the cell peripheral region CPR.

In some embodiments, the first cell wiring line 132 may be located on one first dummy cell DCa of the cell peripheral region CPR. The first cell wiring line 132 is not located on the outermost second dummy cell DCb from among the dummy cells DCa and DCb in the cell peripheral region CPR. The first cell wiring line 132 is not connected to the second dummy cell DCb while being connected to the active cells AC and the first dummy cell DCa.

A first etch stop layer 136 and a third interlayer insulating layer 140 may be formed on the first cell wiring line 132, the buried layer pattern 129, the second interlayer insulating layer 130, and the first peripheral wiring line 134. In some embodiments, the first etch stop layer 136 may include a silicon nitride layer. The third interlayer insulating layer 140 may include the same material as the second interlayer insulating layer 130.

The second contact plug 138 connected to the first cell wiring line 132 may be formed in the third interlayer insulating layer 140 of the cell array region CAR. The second contact plug 138 may be formed through the third interlayer insulating layer 140 and the first etch stop layer 136 and connected to the first cell wiring lines 132. The second contact plug 138 is connected to the active cells AC and the first dummy cell DCa from among the dummy cells DCa and DCb, but is not connected to the second dummy cell DCb.

A second wiring line 142 may be located on the second contact plug 138 and the third interlayer insulating layer 140. The second wiring line 142 may be located in the cell array region CAR and the peripheral circuit region PCR. A second etch stop layer 144 and a fourth interlayer insulating layer 148 may be formed on the second wiring line 142.

In some embodiments, the second etch stop layer 144 may include a silicon nitride layer. The fourth interlayer insulating layer 148 may include the same material as the second interlayer insulating layer 130.

A third contact plug 146 connected to the second wiring line 142 may be formed in the fourth interlayer insulating layer 148 of the cell array region CAR. The third contact plug 146 may be formed to pass through the fourth interlayer insulating layer 148 and the second etch stop layer 144 and be connected to the second wiring line 142. A third wiring line 150 may be located above the third contact plug 146 and inside the fourth interlayer insulating layer 148. The third wiring line 150 may be connected to the third contact plug 146. The third wiring line 150 may be located in the cell array region CAR and the peripheral circuit region PCR.

The third wiring line 150, the third contact plug 146, and the second wiring line 142 may correspond to a bit line BL. The third wiring line 150, third contact plug 146, and second wiring line 142 constituting the bit line BL may be connected to the first cell wiring line 132. The third wiring line 150, the third contact plug 146, and the second wiring line 142 constituting the bit line BL may be connected to the active cells AC and the first dummy cell DCa from among the dummy cells DCa and DCb and may not be connected to the second dummy cell DCb.

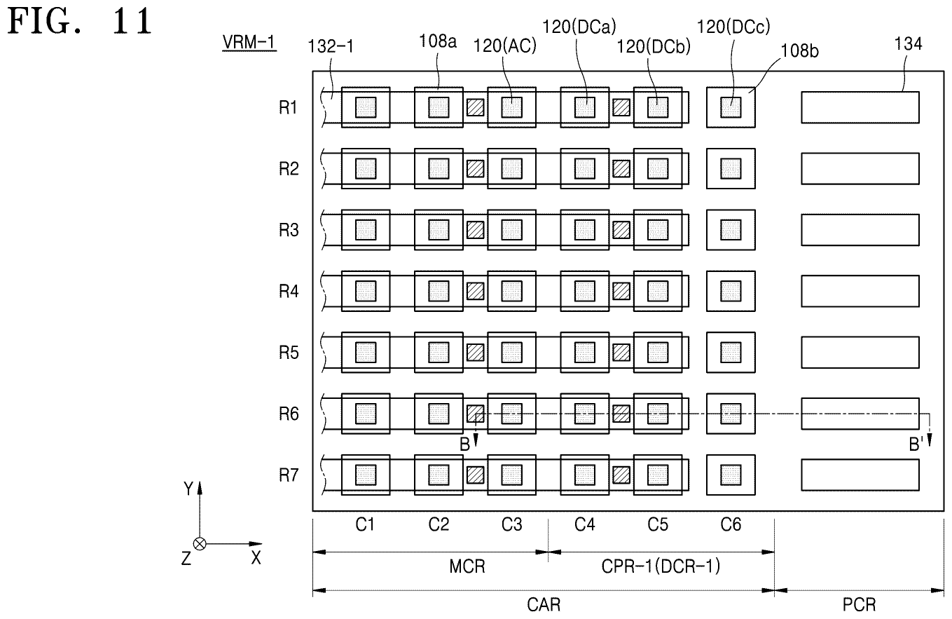

FIG. 11 is a partial circuit diagram showing a variable resistance memory device according to at least one embodiment.

In detail, a variable resistance memory device VRM-1 may be the same as in FIG. 8 except that the arrangement of a cell peripheral region CPR-1, that is, the arrangement of a dummy cell region DCR-1 and the arrangement of first cell wiring lines 132-1 are different therefrom. In FIG. 11, the same description as in FIG. 8 is briefly explained or omitted.

The variable resistance memory device VRM-1 may include the cell array region CAR and the peripheral circuit region PCR. In the cell array region CAR, a plurality of memory cells AC, DCa, DCb, and DCc may be apart from each other in the first direction (X direction, row direction) and a second direction (Y direction, column direction) perpendicular to the first direction (X direction, row direction).

The cell array region CAR may include the main cell region MCR in which active cells AC from among the memory cells AC, DCa, DCb, and DCc are located and the cell peripheral region CPR-1 which is outside the main cell region MCR and in which the dummy cells DCa, DCb, and DCc are located in N columns (N is a natural number greater than or equal to 2), for example, columns C4, C5, and C6 from among the memory cells AC, DCa, DCb, and DCc.

In some embodiments, the dummy cells DCa, DCb, and DCc may include first dummy cells DCa and DCb and second dummy cells DCc. The first dummy cells DCa and DCb may be located in two columns C4 and C5, and the second dummy cells DCc may be located in one column C6. In some embodiments, unlike FIG. 11, the first dummy cells DCa and DCb may be arranged in three or more columns, and the second dummy cells DCc may also be arranged in two or more columns. As a result, the first dummy cells DCa and DCb and the second dummy cells DCc may be arranged in at least two or more columns.

The peripheral circuit region PCR may be located on one side of the cell array region CAR. The cell array region CAR may include the cell peripheral region CPR-1 located between the main cell region MCR and the peripheral circuit region PCR. The cell peripheral region CPR-1 may include the dummy cell region DCR-1 in which the dummy cells DCa, DCb, and DCc required for a manufacturing process are located.

The variable resistance memory device VRM-1 may include variable resistance pattern structures 120 that are regularly arranged apart from each other in the first direction (X direction, row direction) and the second direction (Y direction, column direction). E (E is a natural number greater than or equal to 1) variable resistance pattern structures 120 may be arranged in the first direction (X direction, row direction), and F (F is a natural number greater than or equal to 1) variable resistance pattern structures 120 may be arranged in the second direction (Y direction, column direction).

For convenience, FIG. 11 shows 7×6 matrix arrangement in which seven variable resistance pattern structures 120 of R¹ to R7 are arranged in the first direction (X direction, row direction) and six variable resistance pattern structures 120 of C₁ to C₆ are arranged in the second direction (Y direction, column direction), in the cell array region CAR.

The variable resistance pattern structures 120 may include the memory cells AC, DCa, and DCb. In the variable resistance pattern structures 120, the memory cells AC located in the main cell region MCR may include active cells. In the variable resistance pattern structures 120, the memory cells DCa, DCb, and DCc located in the cell peripheral region CPR-1 and the dummy cell region DCR-1 may include dummy cells.

The variable resistance pattern structures 120 may be located on first contact plugs 108a and 108b. The first contact plugs 108a and 108b may include a cell contact plug 108a located in the cell array region CAR and a dummy cell contact plug 108b located in the dummy cell region DCR-1.

The variable resistance pattern structures 120 may include a variable resistance layer, that is, a MTJ layer or a MTJ pattern. The variable resistance pattern structures 120 located in the cell array region CAR may include the active cells AC that perform a write operation and a read operation. The variable resistance pattern structures 120 located in the cell peripheral region CPR-1 (that is, the dummy cell region DCR-1) may include the dummy cells DCa, DCb, and DCc that do not perform a write operation and a read operation.

According to the inventive concepts, in the cell peripheral region CPR-1, that is, the dummy cell region DCR-1 located outside the main cell region MCR in the second direction (Y direction, column direction), the dummy cells DCa, DCb, and DCc may be located in N columns (N is a natural number greater than or equal to 2), for example, the columns C4, C5, and C6.

In some embodiments, as shown in FIG. 11, in the cell peripheral region CPR, that is, the dummy cell region DCR-1 located outside the main cell region MCR in the second direction (Y direction, column direction), the dummy cells DCa, DCb, and DCc may be located in the three columns C4, C5, and C6.

In the variable resistance memory device VRM, the first cell wiring lines 132-1 may extend long in the first direction (X direction, row direction) on the variable resistance pattern structures 120. The first cell wiring lines 132-1 may be arranged apart from each other in the second direction (Y direction, column direction).

In some embodiments, differently from FIG. 11, the first cell wiring lines 132-1 may extend long in the second direction (Y direction, column direction) on the variable resistance pattern structures 120 and may be apart from each other in the in the first direction (X direction, row direction).

The first cell wiring lines 132-1 may be arranged to extend from the cell array region CAR to a portion of the cell peripheral region CPR-1 in the first direction (X direction, row direction). In some embodiments, the first cell wiring lines 132-1 may extend on the first dummy cells DCa and DCb of the cell peripheral region CPR-1 from the cell array region CAR in the first direction (X direction, row direction). The first cell wiring lines 132-1 may extend on two of the three columns C4, C5, and C6 constituting the dummy cells DCa, DCb, and DCc from the cell array region CAR in the first direction (X direction).

The first cell wiring lines 132-1 does not extend in the first direction (X direction, row direction) from the cell array region CAR to the second dummy cells DCc, which are the outermost portion of the cell peripheral region CPR-1.

In other words, from among the dummy cells DCa, DCb, and DCc, the first dummy cells DCa and DCb located in at least one column adjacent to the main cell region MCR, for example, C1 to C3, are connected to the first cell wiring line 132-1. From among the dummy cells DCa, DCb, and DCc, the second dummy cells DCc located in at least one column adjacent to the peripheral circuit region PCR, for example, C6, are not connected to the first cell wiring line 132-1.

The variable resistance memory device VRM-1 includes first peripheral wiring lines 134 extending in the first direction (X direction, row direction). The first peripheral wiring lines 134 may not be connected to the first cell wiring lines 132-1.

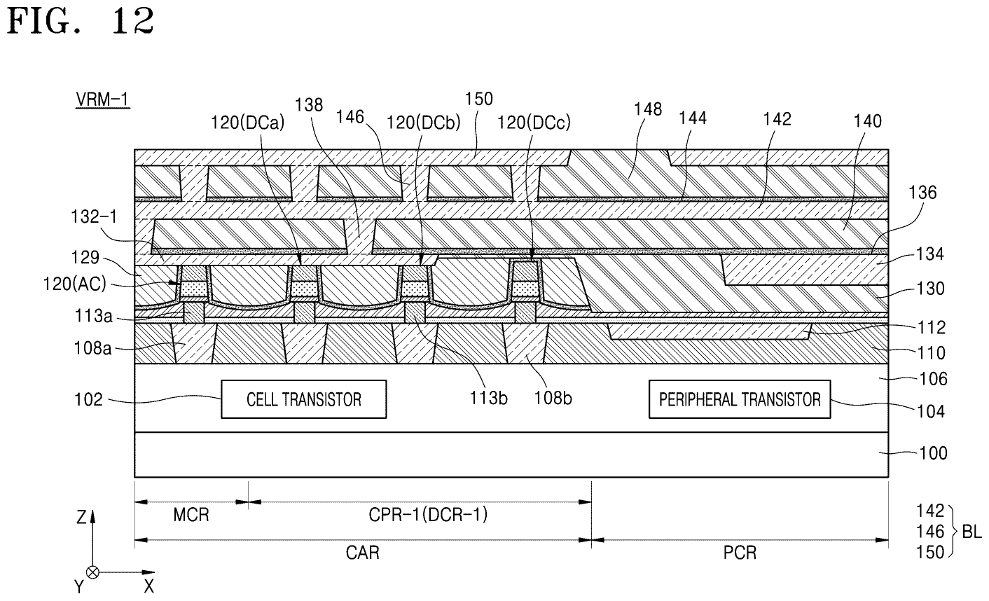

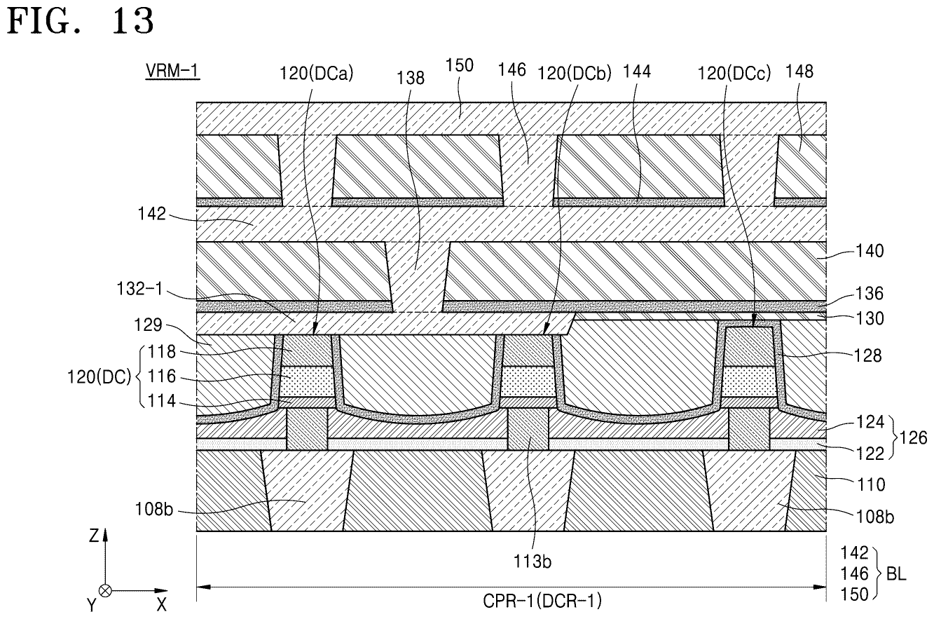

The cell array region CAR may include second contact plugs 138 connecting the first cell wiring lines 132 to bit lines BL (in FIGS. 12 and 13). Like the first cell wiring lines 132-1, the bit lines BL (in FIGS. 12 and 13) may extend long in the first direction (X direction, row direction) and may be arranged apart from each other in the second direction (Y direction, column direction).

The first cell wiring lines 132-1 does not extend in the first direction (X direction, row direction) from the cell array region CAR to the second dummy cells DCc, which are the outermost portion of the cell peripheral region CPR-1. Accordingly, the generation of metal foreign substances in the main cell region MCR is prevented (or mitigated) during a photoetching process for forming the first cell wiring lines 132-1.

As a result, in the variable resistance memory device VRM-1, occurrence of short circuit defects in the second direction (Y direction) due to metal foreign substances (or contaminates), may be suppressed in the bit lines BL (in FIGS. 12 and 13) connected to the first cell wiring lines 132-1.

FIG. 12 is a cross-sectional view of a variable resistance memory device taken along a line B-B′ of FIG. 11, and FIG. 13 is a partially enlarged cross-sectional view of FIG. 12.

In detail, the variable resistance memory device VRM-1 may be the same as in FIGS. 9 and 10 except that the configuration of the dummy cell contact plugs 108b of the cell peripheral region CPR-1, that is, the dummy cell region DCR-1 and the configuration of the first cell wiring lines 132-1 are different therefrom. In FIGS. 12 and 13, the same description as in FIGS. 9 and 10 is briefly described or omitted.

The variable resistance memory device VRM-1 may include the substrate 100 divided into the cell array region CAR and the peripheral circuit region PCR. The cell array region CAR may include the main cell region MCR, and the dummy cell region DCR-1 located on one side of the main cell region MCR.

In the cell array region CAR, the cell peripheral region CPR-1 may be located between the main cell region MCR and the peripheral circuit region PCR. The cell peripheral region CPR-1 may include the dummy cell region DCR-1 in which the dummy cells DCa, DCb, and DCc are located. The peripheral circuit region PCR may be located around the cell array region CAR, for example, on one side of the cell array region CAR, and may be a region in which core/ferry circuits are formed.

The cell transistor 102 may be formed on the substrate 100 in the cell array region CAR. The peripheral transistor 104 may be formed on the substrate 100 in the peripheral circuit region PCR. A level at which the cell transistor 102 and the peripheral transistor 104 are formed may be referred to as the transistor level layer 106.

The cell contact plugs 108a that are connected to the cell transistor 102 are formed in the main cell region MCR on the transistor level layer 106. The dummy cell contact plugs 108b that are not connected to the cell transistor 102 are located in the dummy cell region DCR on the transistor level layer 106. The cell contact plugs 108a and the dummy cell contact plugs 108b constitute first contact plugs 108a and 108b.

The first peripheral wiring layer 112 connected to the peripheral transistor 104 may be located on the peripheral circuit region PCR on the transistor level layer 106. The first contact plugs 108a and 108b and the first peripheral wiring layer 112 may be insulated by the first interlayer insulating layer 110.

The pad electrodes 113a and 113b may be located on the first contact plugs 108a and 108b in the cell array region CAR. The pad electrodes 113a and 113b may include cell pad electrodes 113a and dummy cell pad electrodes 113b. The cell pad electrodes 113a may be located on the cell contact plugs 108a. The dummy cell pad electrodes 113b may be located on the dummy cell contact plugs 108b.

The pad separation insulating layer 126 may be provided between the pad electrodes 113a and 113b and on the first interlayer insulating layer 110 and the first peripheral wiring layer 112. The pad separation insulating layer 126 may include the first pad separation insulating layer 122 and the second pad separation insulating layer 124 formed on the first pad separation insulating layer 122.

The variable resistance pattern structure 120 constituting a memory cell may be provided on the pad electrodes 113a and 113b. The variable resistance pattern structure 120 may have a structure in which the lower electrode 114, the MTJ pattern 116, and the upper electrode 118 are stacked. The MTJ pattern 116 may constitute a variable resistance layer and, as described above, may include the pinned layer PL, the tunnel barrier layer TBL, and the free layer FL.

The variable resistance pattern structure 120 located in the cell array region CAR may constitute the active cells AC. The active cells AC may be located on cell contact plugs 108a. The active cells AC may be connected to the cell contact plugs 108a through the cell pad electrodes 113a. The active cells AC may perform a write operation and a read operation.

The dummy cells DCa, DCb, and DCc that do not perform a write operation and a read operation may be located in the variable resistance pattern structures 120 located in the cell peripheral region CPR-1, that is, the dummy cell region DCR-1. The dummy cells DCa, DCb, and DCc may be located on the dummy cell contact plugs 108b. The dummy cells DCa, DCb, and DCc may be connected to the dummy cell contact plugs 108b through the dummy cell pad electrodes 113b. For example, in at least some embodiments, the dummy cell pad electrodes 113b may not be connected to a cell transistor 102.

The dummy cells DCa, DCb, and DCc may include at least one first dummy cells DCa and DCb located adjacent to the main cell region MCR and at least one second dummy cell DCc located adjacent to the peripheral circuit region PCR.

The capping layer pattern 128 may be formed on a surface of the pad separation insulating layer 126 while covering a sidewall of the variable resistance pattern structure 120. The buried layer pattern 129 may be formed on the capping layer pattern 128 to fill a space between the variable resistance pattern structures 120.

A step difference may be formed between the cell array region CAR and the peripheral circuit region PCR due to the variable resistance pattern structure 120. The second interlayer insulating layer 130 may be formed on the pad separation insulating layer 126 in the peripheral circuit region PCR to offset the step between the cell array region CAR and the peripheral circuit region PCR.

The first cell wiring line 132-1 may be located on the active cells AC and the first dummy cells DCa and DCb in the variable resistance pattern structures 120. The first cell wiring line 132-1 may be located on the upper electrode 118 of the variable resistance pattern structures 120. The first cell wiring line 132-1 may be located in a portion of the cell peripheral region CPR-1.

In some embodiments, the first cell wiring line 132-1 may be located on two first dummy cells DCa and DCb of the cell peripheral region CPR-1. The first cell wiring line 132-1 is not located on the outermost second dummy cell DCc from among the dummy cells DCa, DCb, and DCc in the cell peripheral region CPR-1. The first cell wiring line 132-1 is not connected to the second dummy cell DCc while being connected to the active cells AC and the first dummy cells DCa and DCb.

The first etch stop layer 136 and the third interlayer insulating layer 140 may be formed on the first cell wiring line 132-1, the buried layer pattern 129, the second interlayer insulating layer 130, and the first peripheral wiring line 134. The second contact plug 138 connected to the first cell wiring line 132 may be formed in the third interlayer insulating layer 140 of the cell array region CAR.

The second contact plug 138 may be formed through the third interlayer insulating layer 140 and the first etch stop layer 136 and connected to the first cell wiring lines 132-1. The second contact plug 138 is connected to the active cells AC and the first dummy cells DCa and DCb from among the dummy cells DCa and DCb, but is not connected to the second dummy cell DCc.

The second wiring line 142 may be located on the second contact plug 138 and the third interlayer insulating layer 140. The second wiring line 142 may be located on the cell array region CAR and the peripheral circuit region PCR. The second etch stop layer 144 and the fourth interlayer insulating layer 148 may be formed on the second wiring line 142.

The third contact plug 146 connected to the second wiring line 142 may be formed in the fourth interlayer insulating layer 148 of the cell array region CAR. The third contact plug 146 may be formed to pass through the fourth interlayer insulating layer 148 and the second etch stop layer 144 and be connected to the second wiring line 142. The third wiring line 150 may be located above the third contact plug 146 and inside the fourth interlayer insulating layer 148. The third wiring line 150 may be connected to the third contact plug 146. The third wiring line 150 may be located in the cell array region CAR and the peripheral circuit region PCR.

The third wiring line 150, the third contact plug 146, and the second wiring line 142 may be the bit line BL. The third wiring line 150, third contact plug 146, and second wiring line 142 constituting the bit line BL may be connected to the first cell wiring line 132-1. The third wiring line 150, the third contact plug 146, and the second wiring line 142 constituting the bit line BL may be connected to the active cells AC and the first dummy cells DCa and DCb from among the dummy cells DCa, DCb, and DCc and may not be connected to the second dummy cell DCc.

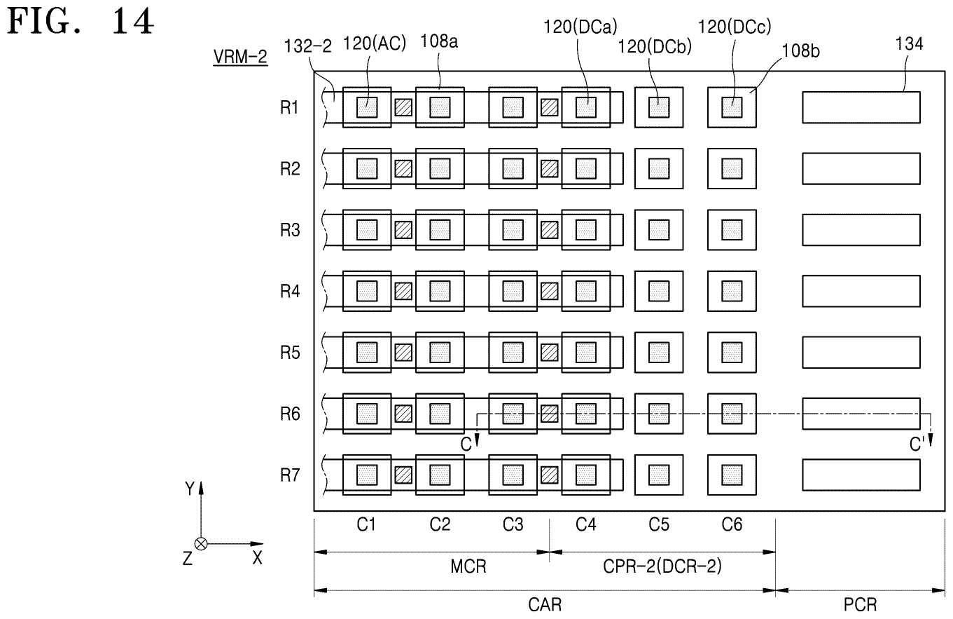

FIG. 14 is a partial circuit diagram showing a variable resistance memory device according to at least one embodiment.

In detail, a variable resistance memory device VRM-2 may be the same as in FIG. 8 except that the arrangement of a cell peripheral region CPR-2, that is, the arrangement of a dummy cell region DCR-2 and the arrangement of first cell wiring lines 132-2 are different therefrom. The variable resistance memory device VRM-2 may be the same as that of FIG. 11 except that the arrangement of the first cell wiring lines 132-2 is different therefrom. In FIG. 14, the same description as in FIGS. 8 and 11 is briefly described or omitted.

The variable resistance memory device VRM-2 may include the cell array region CAR and the peripheral circuit region PCR. In the cell array region CAR, a plurality of memory cells AC, DCa, DCb, and DCc may be apart from each other in the first direction (X direction, row direction) and the second direction (Y direction, column direction) perpendicular to the first direction (X direction, row direction).

The cell array region CAR may include the main cell region MCR in which the active cells AC from among the memory cells AC, DCa, DCb, and DCc are located and the cell peripheral region CPR-2 which is outside the main cell region MCR and in which the dummy cells DCa, DCb, and DCc are located in N columns (N is a natural number greater than or equal to 2), for example, columns C4, C5, and C6 from among the memory cells AC, DCa, DCb, and DCc.

In some embodiments, the dummy cells DCa, DCb, and DCc may include first dummy cells DCa and DCb and the second dummy cells DCc. The first dummy cells DCa and DCb may be located in two columns C4 and C5, and the second dummy cells DCc may be located in one column C6. In some embodiments, unlike FIG. 14, the first dummy cells DCa and DCb may be arranged in three or more columns, and the second dummy cells DCc may also be arranged in two or more columns. As a result, the first dummy cells DCa and DCb and the second dummy cells DCc may be arranged in at least two or more columns.

The peripheral circuit region PCR may be located on one side of the cell array region CAR. The cell array region CAR may include the cell peripheral region CPR-2 located between the main cell region MCR and the peripheral circuit region PCR. The cell peripheral region CPR-2 may include the dummy cell region DCR-2 in which the dummy cells DCa, DCb, and DCc required for a manufacturing process are located.

The variable resistance memory device VRM-2 may include variable resistance pattern structures 120 that are regularly arranged apart from each other in the first direction (X direction, row direction) and the second direction (Y direction, column direction). E (E is a natural number greater than or equal to 1) variable resistance pattern structures 120 may be arranged in the first direction (X direction, row direction) and F (F is a natural number greater than or equal to 1) variable resistance pattern structures 120 may be arranged in the second direction (Y direction, column direction).

For convenience, FIG. 14 shows 7×6 matrix arrangement in which seven variable resistance pattern structures 120 of R1 to R7 are arranged in the first direction (X direction, row direction) and six variable resistance pattern structures 120 of C1 to C6 are arranged in the second direction (Y direction, column direction), in the cell array region CAR.

The variable resistance pattern structures 120 may constitute the memory cells AC, DCa, and DCb. In the variable resistance pattern structures 120, the memory cells AC located in the main cell region MCR may include active cells. In the variable resistance pattern structures 120, the memory cells DCa, DCb, and DCc located in the cell peripheral region CPR-2 and the dummy cell region DCR-2 may include dummy cells.

The variable resistance pattern structures 120 may be located on the first contact plugs 108a and 108b. The first contact plugs 108a and 108b may include a cell contact plug 108a located in the cell array region CAR and the dummy cell contact plug 108b located in the dummy cell region DCR-1.

The variable resistance pattern structures 120 may include a variable resistance layer, that is, a MTJ layer or a MTJ pattern. The variable resistance pattern structures 120 located in the cell array region CAR may include the active cells AC that perform a write operation and a read operation. The variable resistance pattern structures 120 located in the cell peripheral region CPR-2, that is, the dummy cell region DCR-2 may include the dummy cells DCa, DCb, and DCc that do not perform a write operation and a read operation.

According to the inventive concepts, in the cell peripheral region CPR-2, that is, the dummy cell region DCR-2 located outside the main cell region MCR in the second direction (Y direction, column direction), the dummy cells DCa, DCb, and DCc may be located in N columns (N is a natural number greater than or equal to 2), for example, the columns C4, C5, and C6.

In some embodiments, as shown in FIG. 8, in the cell peripheral region CPR-2, that is, the dummy cell region DCR-2 located outside the main cell region MCR in the second direction (Y direction, column direction), the dummy cells DCa, DCb, and DCc may be located in the three columns C4, C5, and C6.

In the variable resistance memory device VRM, the first cell wiring lines 132-2 may extend long in the first direction (X direction, row direction) on the variable resistance pattern structures 120. The first cell wiring lines 132-2 may be arranged apart from each other in the second direction (Y direction, column direction).

In some embodiments, differently from FIG. 14, the first cell wiring lines 132-2 may extend long in the second direction (Y direction, column direction) on the variable resistance pattern structures 120 and may be apart from each other in the in the first direction (X direction, row direction).

The first cell wiring lines 132-2 may be arranged to extend from the cell array region CAR to a portion of the cell peripheral region CPR-2 in the first direction (X direction, row direction). In some embodiments, the first cell wiring lines 132-2 may extend on the first dummy cells DCa of the cell peripheral region CPR-2 from the cell array region CAR in the first direction (X direction, row direction). The first cell wiring lines 132-2 may extend on one of the three columns C4, C5, and C6 constituting the dummy cells DCa, DCb, and DCc from the cell array region CAR in the first direction (X direction).

The first cell wiring lines 132-2 do not extend in the first direction (X direction, row direction) from the cell array region CAR to the second dummy cells DCc, which are the outermost portion of the cell peripheral region CPR-2.

In other words, from among the dummy cells DCa, DCb, and DCc, the first dummy cells DCa and DCb located in at least one column adjacent to the main cell region MCR, for example, C1 to C3, are connected to the first cell wiring line 132-2. From among the dummy cells DCa, DCb, and DCc, the second dummy cells DCb and DCc located in at least one column adjacent to the peripheral circuit region PCR, for example, C5 and C6, are not connected to the first cell wiring line 132-2.

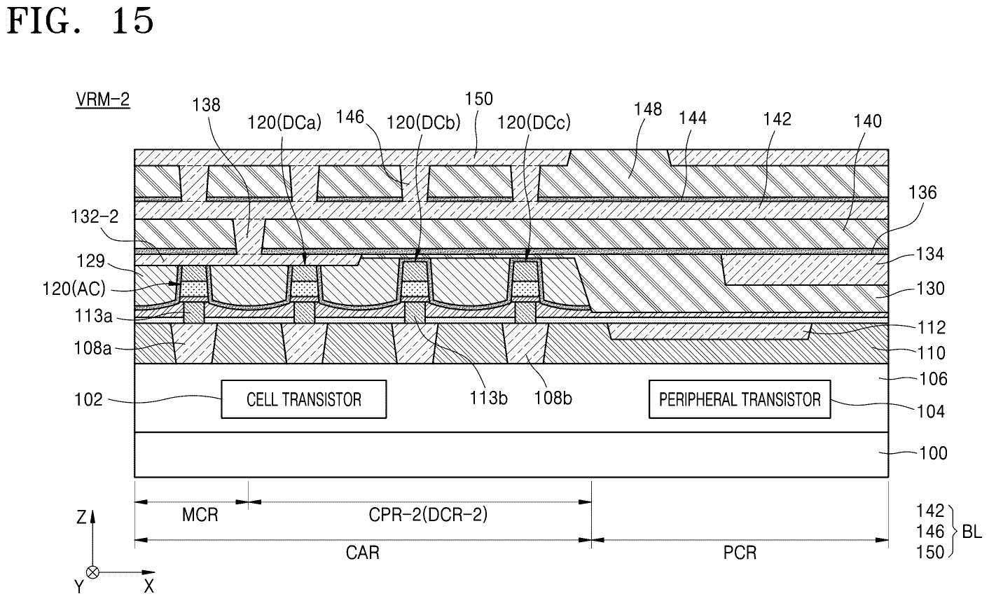

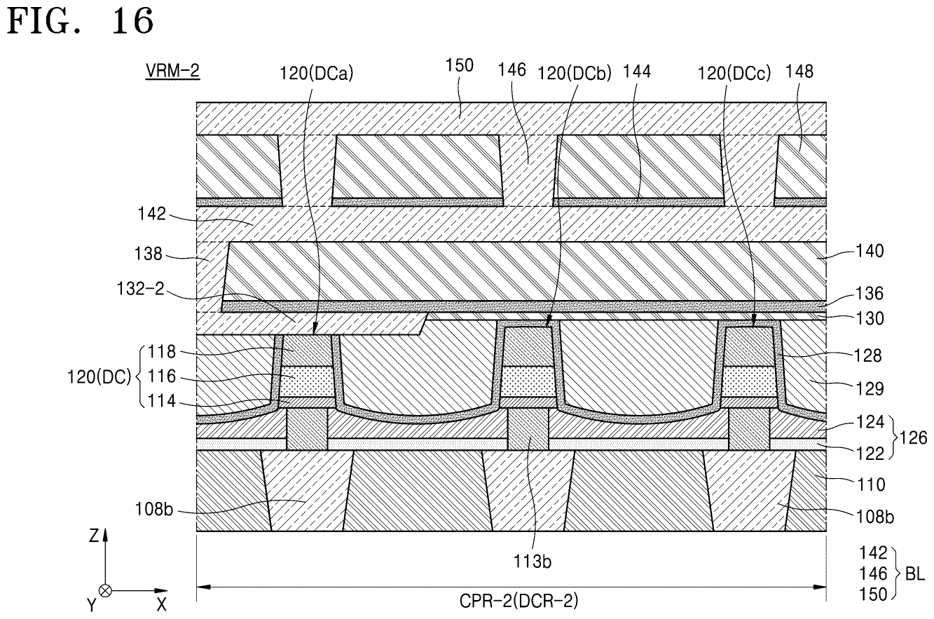

The variable resistance memory device VRM-2 includes the first peripheral wiring lines 134 extending in the first direction (X direction, row direction). The first peripheral wiring lines 134 may not be connected to the first cell wiring lines 132-2. The cell array region CAR may include second contact plugs 138 connecting the first cell wiring lines 132-2 to bit lines BL (in FIGS. 15 and 16). Like the first cell wiring lines 132-2, the bit lines BL (in FIGS. 15 and 16) may extend long in the first direction (X direction, row direction) and may be arranged apart from each other in the second direction (Y direction, column direction).

The first cell wiring lines 132-2 does not extend in the first direction (X direction, row direction) from the cell array region CAR to the second dummy cells DCb and DCc, which are the outermost portion of the cell peripheral region CPR-1. Accordingly, the generation of metal foreign substances in the main cell region MCR is prevented (or mitigated) during a photoetching process for forming the first cell wiring lines 132-2.

As a result, in the variable resistance memory device VRM-1, occurrence of short circuit defects in the second direction (Y direction) due to metal foreign substances may be suppressed in the bit lines BL (in FIGS. 14 and 15) connected to the first cell wiring lines 132-2.

FIG. 15 is a cross-sectional view of a variable resistance memory device taken along a line C-C′ of FIG. 14, and FIG. 16 is a partially enlarged cross-sectional view of FIG. 15.

In detail, a variable resistance memory device VRM-2 may be the same as in FIGS. 9 and 10 except that the configuration of the dummy cell contact plugs 108b of the cell peripheral region CPR-2, that is, the dummy cell region DCR-2 and the configuration of the first cell wiring lines 132-2 are different therefrom.

The variable resistance memory device VRM-2 may be the same as that of FIGS. 12 and 13 except that the configuration of the first cell wiring lines 132-2 in the cell peripheral region CPR-2 is different therefrom. In FIGS. 15 and 16, the same description as in FIGS. 9, 10, 12, and 13 is briefly described or omitted.

The variable resistance memory device VRM-2 may include the substrate 100 divided into the cell array region CAR and the peripheral circuit region PCR. The cell array region CAR may include the main cell region MCR, and the dummy cell region DCR-2 located on one side of the main cell region MCR.

In the cell array region CAR, the cell peripheral region CPR-2 may be located between the main cell region MCR and the peripheral circuit region PCR. The cell peripheral region CPR-2 may include the dummy cell region DCR-2 in which the dummy cells DCa, DCb, and DCc are located. The peripheral circuit region PCR may be located around the cell array region CAR, for example, on one side of the cell array region CAR, and may be a region in which core/ferry circuits are formed.

The cell transistor 102 may be formed on the substrate 100 in the cell array region CAR. The peripheral transistor 104 may be formed on the substrate 100 in the peripheral circuit region PCR. A level at which the cell transistor 102 and the peripheral transistor 104 are formed may be referred to as the transistor level layer 106.

The cell contact plugs 108a that are connected to the cell transistor 102 are formed in the main cell region MCR on the transistor level layer 106. The dummy cell contact plugs 108b that are not connected to the cell transistor 102 are located in the dummy cell region DCR on the transistor level layer 106. The cell contact plugs 108a and the dummy cell contact plugs 108b constitute first contact plugs 108a and 108b.

The first peripheral wiring layer 112 connected to the peripheral transistor 104 may be located on the peripheral circuit region PCR on the transistor level layer 106. The first contact plugs 108a and 108b and the first peripheral wiring layer 112 may be insulated by the first interlayer insulating layer 110.

The pad electrodes 113a and 113b may be located on the first contact plugs 108a and 108b in the cell array region CAR. The pad electrodes 113a and 113b may include the cell pad electrodes 113a and the dummy cell pad electrodes 113b. The cell pad electrodes 113a may be located on the cell contact plugs 108a. The dummy cell pad electrodes 113b may be located on the dummy cell contact plugs 108b.

The pad separation insulating layer 126 may be provided between the pad electrodes 113a and 113b and on the first interlayer insulating layer 110 and the first peripheral wiring layer 112. The pad separation insulating layer 126 may include the first pad separation insulating layer 122 and the second pad separation insulating layer 124 formed on the first pad separation insulating layer 122.

The variable resistance pattern structure 120 constituting a memory cell may be provided on the pad electrodes 113a and 113b. The variable resistance pattern structure 120 may have a structure in which the lower electrode 114, the MTJ pattern 116, and the upper electrode 118 are stacked. The MTJ pattern 116 may constitute a variable resistance layer and, as described above, may include the pinned layer PL, the tunnel barrier layer TBL, and the free layer FL.

The variable resistance pattern structure 120 located in the cell array region CAR may constitute the active cells AC. The active cells AC may be located on cell contact plugs 108a. The active cells AC may be connected to the cell contact plugs 108a through the cell pad electrodes 113a. The active cells AC may perform a write operation and a read operation.

The dummy cells DCa, DCb, and DCc that do not perform a write operation and a read operation may be located in the variable resistance pattern structures 120 located in the cell peripheral region CPR-2, that is, the dummy cell region DCR-2. The dummy cells DCa, DCb, and DCc may be located on the dummy cell contact plugs 108b. The dummy cells DCa, DCb, and DCc may be connected to the dummy cell contact plugs 108b through the dummy cell pad electrodes 113b.

The dummy cells DCa, DCb, and DCc may include at least one first dummy cells DCa and DCb located adjacent to the main cell region MCR and at least one second dummy cell DCc located adjacent to the peripheral circuit region PCR.

The capping layer pattern 128 may be formed on a surface of the pad separation insulating layer 126 while covering a sidewall of the variable resistance pattern structure 120. The buried layer pattern 129 may be formed on the capping layer pattern 128 to fill a space between the variable resistance pattern structures 120.

A step difference may be formed between the cell array region CAR and the peripheral circuit region PCR due to the variable resistance pattern structure 120. The second interlayer insulating layer 130 may be formed on the pad separation insulating layer 126 in the peripheral circuit region PCR to offset the step between the cell array region CAR and the peripheral circuit region PCR.

The first cell wiring line 132-2 may be located on the active cells AC and the first dummy cell DCa in the variable resistance pattern structures 120. The first cell wiring line 132-2 may be located on the upper electrode 118 of the variable resistance pattern structures 120. The first cell wiring line 132-2 may be located in a portion of the cell peripheral region CPR-2.

In some embodiments, the first cell wiring line 132-2 may be located on one first dummy cell DCa of the cell peripheral region CPR-1. The first cell wiring line 132-2 is not located on outer second dummy cells DCb and DCc from among the dummy cells DCa, DCb, and DCc in the cell peripheral region CPR-2. The first cell wiring line 132-2 is not connected to the second dummy cells DCb and DCc while being connected to the active cells AC and the first dummy cell DCa.

The first etch stop layer 136 and the third interlayer insulating layer 140 may be formed on the first cell wiring line 132-2, the buried layer pattern 129, the second interlayer insulating layer 130, and the first peripheral wiring line 134. The second contact plug 138 connected to the first cell wiring line 132-2 may be formed in the third interlayer insulating layer 140 of the cell array region CAR.

The second contact plug 138 may be formed through the third interlayer insulating layer 140 and the first etch stop layer 136 and connected to the first cell wiring lines 132-2. The second contact plug 138 is connected to the active cells AC and the first dummy cell DCa from among the dummy cells DCa, DCb, and DCc but is not connected to the second dummy cells DCb and DCc.

The second wiring line 142 may be located on the second contact plug 138 and the third interlayer insulating layer 140. The second wiring line 142 may be located on the cell array region CAR and the peripheral circuit region PCR. The second etch stop layer 144 and the fourth interlayer insulating layer 148 may be formed on the second wiring line 142.

The third contact plug 146 connected to the second wiring line 142 may be formed in the fourth interlayer insulating layer 148 of the cell array region CAR. The third contact plug 146 may be formed to pass through the fourth interlayer insulating layer 148 and the second etch stop layer 144 and be connected to the second wiring line 142. The third wiring line 150 may be located above the third contact plug 146 and inside the fourth interlayer insulating layer 148. The third wiring line 150 may be connected to the third contact plug 146. The third wiring line 150 may be located in the cell array region CAR and the peripheral circuit region PCR.

The third wiring line 150, the third contact plug 146, and the second wiring line 142 may be the bit line BL. The third wiring line 150, third contact plug 146, and second wiring line 142 constituting the bit line BL may be connected to the first cell wiring line 132-2. The third wiring line 150, the third contact plug 146, and the second wiring line 142 constituting the bit line BL may be connected to the active cells AC and the first dummy cell DCa from among the dummy cells DCa, DCb, and DCc and may not be connected to the second dummy cells DCb and DCc.

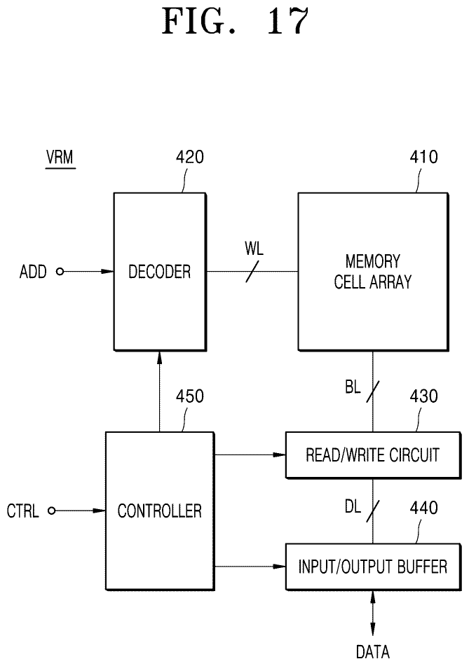

FIG. 17 is a configuration diagram showing a variable resistance memory device according to at least one embodiment.

In detail, the variable resistance memory device VRM according to at least one embodiment includes a memory cell array 410, a decoder 420, a read/write circuit 430, an input/output buffer 440, and a controller 450. The memory cell array 410 is described previously and therefore description thereof is omitted. The variable resistance memory device VRM of FIG. 17 may be the same as the variable resistance memory devices VRM-1 and VRM-2 described above except for the configuration of the memory cell array 410.

A plurality of memory cells in the memory cell array 410 are connected to the decoder 420 through a word line WL and connected to the read/write circuit 430 through the bit line BL. The decoder 420 receives an external address ADD and decodes a row address and a column address to be accessed in the memory cell array 410 under control of the controller 450 operating according to a control signal CTRL.

The read/write circuit 430 receives data DATA from the input/output buffer 440 and a data line DL and records data in a selected memory cell of the memory cell array 410 under control of the controller 450 or provides data read from the selected memory cell of the memory cell array 410 to the input/output buffer 440 under control of the controller 450.

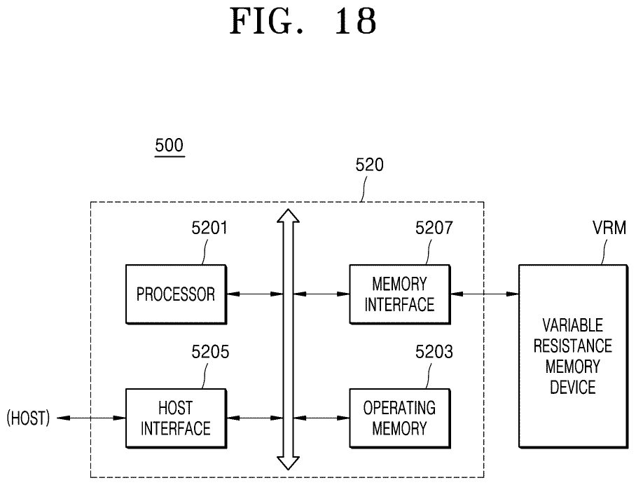

FIG. 18 is a configuration diagram of a data processing system including a variable resistance memory device according to at least one embodiment.

In detail, a data processing system 500 may include a memory controller 520 connected between a host and the variable resistance memory device VRM. The memory controller 520 may be configured to access the variable resistance memory device VRM in response to a request of the host.

The variable resistance memory device VRM of FIG. 18 may be, for example, one of the variable resistance memory devices VRM, VRM-1, and/or VRM-2 described above. The memory controller 520 may include a processor 5201, an operating memory 5203, a host interface 5205, and a memory interface 5207.

The processor 5201 may control the overall operation of the memory controller 520, and the operating memory 5203 may store an application, data, and a control signal necessary for the memory controller 520 to operate. The host interface 5205 performs protocol conversion for data/control signal exchange between the host and the memory controller 520.

The memory interface 5207 performs protocol conversion for data/control signal exchange between the memory controller 520 and the variable resistance memory device VRM. The variable resistance memory device VRM is the same as described above and a description thereof is therefore omitted. The data processing system 500 according to at least one embodiment may include a memory card, but is not limited thereto.

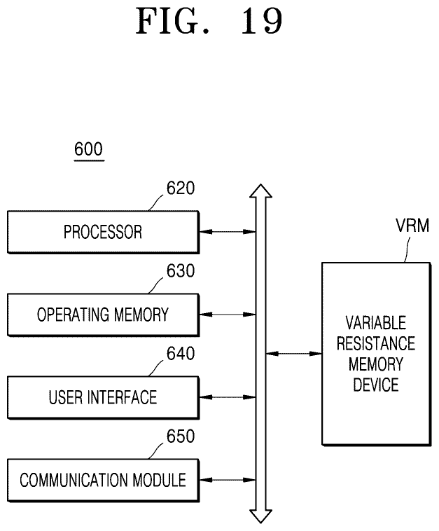

FIG. 19 is a configuration diagram of a data processing system including a variable resistance memory device according to at least one embodiment.

In detail, a data processing system 600 may include the variable resistance memory device VRM, a processor 620, an operating memory 630, and a user interface 640 and may further include a communication module 650 if necessary. The processor 620 may include a central processing device. The variable resistance memory device VRM of FIG. 19 may be replaced by the variable resistance memory devices VRM-1 and VRM-2 described above.

The operating memory 630 stores an application program, data, and a control signal necessary for the data processing system 600 to operate. The user interface 640 provides an environment in which a user is capable of accessing the data processing system 600 and provides a data processing process and results of the data processing system 600 to the user.

The variable resistance memory device VRM of FIG. 18 may be, for example, one of the variable resistance memory devices VRM, VRM-1, and/or VRM-2 described above, and a description thereof is therefore omitted. The data processing system may be used as a disk device, used as an internal/external memory card in a portable electronic device, or used as an image processor and other application chipsets.

The variable resistance memory device according to the inventive concepts may include dummy cells in a cell peripheral region of one side of a main cell region to improve process reliability.

In the variable resistance memory device according to the inventive concepts, a cell wiring line is connected to first dummy cells located in one column adjacent to a main cell region from among dummy cells, and a cell wiring line is not connected to second dummy cells located in at least one column adjacent to a peripheral circuit region. Accordingly, the variable resistance memory device may suppress occurrence of short circuit defects between bit lines connected to cell wiring lines.

The inventive concepts have been described above with reference to the embodiments shown in the drawings, but these are merely exemplary, and those skilled in the art will understand that various modifications, substitutions, and other equivalent embodiments are possible therefrom. The embodiments described above are to be understood in all respects as illustrative and to be understood as not restrictive. The true technical scope of the inventive concepts is to be determined by the technical spirit of the claims.

While the inventive concepts have been particularly shown and described with reference to embodiments thereof, it will be understood that various changes in form and details may be made therein without departing from the spirit and scope of the following claims.

What is claimed is:

1. A variable resistance memory device comprising:
a cell array region including a plurality of memory cells spaced apart from each other in a row direction and in a column direction perpendicular to the row direction, the cell array region including
a main cell region in which a plurality of active cells from among the plurality of memory cells are spaced apart from each other, and
a dummy cell region in which dummy cells, from among the plurality of memory cells, are located in N (N is a natural number greater than or equal to 2) columns such that the dummy cell region is outside the main cell region; and
a peripheral circuit region surrounding the cell array region,
wherein first dummy cells located in at least one column adjacent to the main cell region from among the dummy cells are connected to a first cell wiring line, and
second dummy cells located in at least one column adjacent to the peripheral circuit region from among the dummy cells are not connected to the first cell wiring line.

2. The variable resistance memory device of claim 1, wherein at least one of the plurality of memory cells includes a variable resistance pattern structure in which a lower electrode, a magnetic tunnel junction pattern, and an upper electrode are stacked.

3. The variable resistance memory device of claim 1, wherein
the active cells include memory cells, of the plurality of memory cells, configured to perform write and read operations, and
the dummy cells include memory cells, of the plurality of memory cells, that are not configured to perform the write and read operations.

4. The variable resistance memory device of claim 1, wherein the second dummy cells are included in an outermost column of the main cell region.

5. The variable resistance memory device of claim 1, wherein the second dummy cells are arranged in an outer N−1 column of the cell array region.

6. The variable resistance memory device of claim 1, wherein
the first cell wiring line extends in the row direction, and
the first cell wiring line includes a plurality of first cell wiring lines that are spaced apart from each other in the column direction.

7. The variable resistance memory device of claim 1, wherein
the first dummy cells are connected to a bit line through the first cell wiring line above the memory cells,
the bit line includes a plurality of wiring lines, and
the second dummy cells are not connected to the bit line above the memory cells.

8. A variable resistance memory device comprising:
a cell array region including a plurality of memory cells spaced apart in an array including E (E is a natural number greater than or equal to 1) rows and F (F is a natural number greater than or equal to 1) a columns, the cell array region including
a main cell region including a plurality of active cells, from among the plurality of memory cells, spaced apart from each other, and
a cell peripheral region including dummy cells, from among the plurality of memory cells, in N (N is a natural number greater than or equal to 2) columns such that the dummy cells are outside the main cell region; and
a peripheral circuit region surrounding the cell peripheral region,
wherein first dummy cells located in at least one column adjacent to the main cell region from among the dummy cells are connected to a first cell wiring line, and
second dummy cells located in at least one of an outermost column of the cell array region or in an outer N−1 column of the cell array region are not connected to the first cell wiring line.

9. The variable resistance memory device of claim 8, wherein at least one of the plurality of memory cells includes a variable resistance pattern structure in which a lower electrode, a magnetic tunnel junction pattern, and an upper electrode are stacked.

10. The variable resistance memory device of claim 8, wherein
the active cells include memory cells, of the plurality of memory cells, configured to perform write and read operations, and
the dummy cells include memory cells, of the plurality of memory cells, that are not configured to perform the write and read operations.

11. The variable resistance memory device of claim 8, wherein
the E rows are spaced apart in a row direction,
the F columns are spaced part in a column direction,
the first cell wiring line extends in the row direction, and
the first cell wiring line includes a plurality of first cell wiring lines that are spaced apart from each other in the column direction.

12. The variable resistance memory device of claim 8, wherein
the active cells are connected to a bit line through the first cell wiring line above the memory cells, and
the bit line includes a plurality of wiring lines.

13. The variable resistance memory device of claim 8, wherein
the first dummy cells are connected to a bit line through the first cell wiring line above the memory cells,
the bit line includes a plurality of wiring lines, and
the second dummy cells are not connected to the bit line above the memory cells.

14. A variable resistance memory device comprising:
a substrate including
a cell array region including a main cell region and a cell peripheral region including a dummy cell region located at least one side of the main cell region, and
a peripheral circuit region located at one side of the cell array region such that the cell peripheral region is between the peripheral circuit region and the main cell region;
a cell transistor in the cell array region of the substrate;
a plurality of cell contact plugs located in the main cell region above the substrate and connected to the cell transistor;
a plurality of dummy cell contact plugs located in the dummy cell region above the substrate, spaced apart from the cell contact plugs, and not connected to the cell transistor;
a plurality of active cells on the cell contact plugs and connected to the cell transistor through the cell contact plugs;
a plurality of dummy cells on the dummy cell contact plugs and connected to the dummy cell contact plugs, the dummy cells including at least one first dummy cell adjacent to the main cell region and at least one second dummy cell adjacent to the peripheral circuit region;
a first cell wiring line on and connected to the active cells and the at least one first dummy cell and not connected to the at least one second dummy; and
a bit line on the first cell wiring line and connected to the first cell wiring line.

15. The variable resistance memory device of claim 14, wherein at least one of the active cells include a variable resistance pattern structure in which a lower electrode, a magnetic tunnel junction pattern, and an upper electrode are stacked.

16. The variable resistance memory device of claim 14, further comprising:
cell pad electrodes on the cell contact plugs; and
dummy cell pad electrodes on the dummy cell contact plugs.

17. The variable resistance memory device of claim 14, wherein
the active cells are configured to perform write and read operations, and
the dummy cells are not configured to perform the write and read operations.

18. The variable resistance memory device of claim 14, wherein the at least one second dummy cell is in an outermost portion of the cell array region.

19. The variable resistance memory device of claim 14, wherein the at least one second dummy cell is located in outer N−1 (N is a natural number greater than or equal to 2) columns of the cell array region.

20. The variable resistance memory device of claim 14, wherein the bit line further includes
a second wiring line connected to the first cell wiring line through a second contact plug, and
a third wiring line connected to the second wiring line through a third contact plug.
